(19) United States
(12) Patent Application Publication
(10) Pub. No.: US 2024/0290371 A1
(43) Pub. Date: Aug. 29, 2024

(54) MEMORY DEVICE AND METHOD OF OPERATING MEMORY SYSTEM INCLUDING THE SAME

(71) Applicant: Samsung Electronics Co., Ltd., Suwon-si (KR)

(72) Inventors: YOUNGDO UM, Suwon-si (KR); TAEYOUNG OH, Suwon-si (KR); HYE-RAN KIM, Suwon-si (KR)

(21) Appl. No.: 18/499,444

(22) Filed: Nov. 1, 2023

(30) Foreign Application Priority Data
Feb. 28, 2023 (KR) 10-2023-0026762
May 22, 2023 (KR) 10-2023-0065762

(51) Int. Cl. G11C 11/4076; G06F 1/08; G06F 1/12; G06F 12/02; H03K 5/13; H03K 5/156

(52) U.S. Cl. CPC G11C 11/4076; G06F 1/08; G06F 1/12; G06F 12/023; H03K 5/13; H03K 5/1565

(57) ABSTRACT

A memory device includes a divide circuit configured to generate an internal data clock signal based on a data clock signal, wherein the data clock signal has a first voltage level for a first time period and toggles during a second time period consecutive to the first time period, a detect circuit configured to generate a feedback data corresponding to the first voltage level based on the internal data clock signal, and an input/output circuit configured to output the feedback data to an external device.

### CROSS-REFERENCE TO RELATED APPLICATION

This application claims priority to and the benefit of Korean Patent Application No. 10-2023-0026762 filed in the Korean Intellectual Property Office on Feb. 28, 2023, and Korean Patent Application No. 10-2023-0065762 filed in the Korean Intellectual Property Office on May 22, 2023, the entire contents of which are incorporated herein by reference.

### BACKGROUND

### (a) Field of the Invention

The present disclosure relates to semiconductor memory devices. More particularly, the present disclosure relates to memory devices and methods of operating a memory system including the same.

### (b) Description of the Related Art

As operating speeds of processors and memory devices increase, various technologies for high-speed data input/output between the processors and the memory devices are being researched. For example, a recent memory device may receive a data clock separately from a clock from a processor. In this case, the frequency of the data clock may be very high.

However, due to the high frequency of the data clock, it is increasingly difficult for a memory device to accurately detect a logic level transition of a received data clock signal. For example, a data clock signal received by a memory device may include distortion due to inter-symbol interference (ISI). In particular, the influence of the ISI may vary according to a channel between a memory device and a processor.

### SUMMARY

The present disclosure may include embodiments configured to address the above-mentioned technical problem. More specifically, the present disclosure describes embodiments that may provide a memory device and a method of operating a memory system including the same, which may compensate for distortion of a data clock due to ISI.

According to an embodiment of the present inventive concept, a memory device may comprise a divide circuit configured to generate an internal data clock signal based on a data clock signal, wherein the data clock signal has a first voltage level for a first time period and toggles during a second time period consecutive to the first time period, a detect circuit configured to generate a feedback data corresponding to the first voltage level based on the internal data clock signal, and an input/output circuit configured to output the feedback data to an external device.

According to an embodiment of the present inventive concept, a method of operating a memory system including a host device configured to output a data clock signal including a preceding voltage period and a toggle period, and a memory device configured to receive the data clock signal may comprises, providing, by the memory device, a first plurality of feedback data generated based on a first data clock signal having a first voltage level during the preceding voltage period to the host device, providing, by the memory device, a second plurality of feedback data generated based on a second data clock signal having a second voltage level during the preceding voltage period to the host device, determining, by the host device, an optimal preceding voltage level based on the first plurality of feedback data and the second plurality of feedback data, and performing, by the host device, a data clock synchronize operation for the memory device based on a third data clock signal having the optimal preceding voltage level during the preceding voltage period, wherein each of the first plurality of feedback data is generated based on different duty cycle adjuster (DCA) codes, and each of the second plurality of feedback data is generated based on the different DCA codes.

According to an embodiment of the present inventive concept, a method of operating a memory system including a host device and a memory device, comprising, providing, by the host device, a first preceding voltage training command to the memory device, transmitting, by the host device, a first data clock signal to the memory device, wherein the first data clock signal is configured to have a first voltage level from a first time point to a second time point, to toggle from the second time point to a third time point, and to cease togglilng after the third time point, providing, by the memory device, a first feedback data for the first voltage level to the host device in response to the first preceding voltage training command after a first time length has elapsed from the third time point, providing, by the host device, a second preceding voltage training command to the memory device, transmitting, by the host device, a second data clock signal to the memory device, wherein the second data clock signal is configured to have a second voltage level from a fourth time point to a fifth time point, to toggle from the fifth time point to a sixth time point, and to cease toggling after the sixth time point, and providing, by the memory device, a second feedback data for the second voltage level in response to the second preceding voltage training command after the first time length has elapsed from the sixth time point.

### BRIEF DESCRIPTION OF THE DRAWINGS

FIG. 1 is a block diagram illustrating a memory system according to an embodiment of the present disclosure.

FIG. 2 is a diagram illustrating an ideal voltage level of a data clock signal provided to the memory device of FIG. 1.

FIG. 3 is a diagram illustrating a voltage level of a data clock signal provided to the memory device of FIG. 1.

FIG. 4 is a diagram illustrating a voltage level of a data clock signal according to an embodiment of the present disclosure.

FIGS. 5A to 5B are diagrams illustrating the relationship between a magnitude of a preceding voltage level and first to fourth duty rates of FIG. 4.

FIG. 6 is a block diagram illustrating a configuration of a memory device according to an embodiment of the present disclosure.

FIG. 7 is a diagram illustrating a duty cycle adjustment (DCA) code and logic levels of adjusted data clock signals according to an embodiment of the present disclosure.

FIG. 8 is a flowchart illustrating an operation of the memory system of FIG. 1 according to an embodiment of the present disclosure.

FIG. 9 is a flowchart illustrating operation S120 of FIG. 8 in more detail according to an embodiment of the present disclosure.

FIG. 10 is a flowchart illustrating operations S122 to S123 of FIG. 9 in more detail according to an embodiment of the present disclosure.

FIG. 11 is a block diagram illustrating the memory device of FIG. 6 implemented according to an embodiment of the present disclosure.

FIG. 12 is a timing diagram illustrating an operation of the memory device of FIG. 11 according to an embodiment of the present disclosure.

FIGS. 13A to 13C are timing diagrams illustrating operations of a memory device of FIG. 11 according to another embodiment of the present disclosure.

FIG. 14 is a flowchart illustrating an operation of a counter of FIG. 11 in more detail according to an embodiment of the present disclosure.

FIG. 15 is a block diagram illustrating the memory device of FIG. 6 implemented according to an embodiment of the present disclosure.

FIG. 16 is a timing diagram illustrating an operation of the memory device of FIG. 15 according to an embodiment of the present disclosure.

FIGS. 17A to 17B are timing diagrams illustrating operations of a memory device of FIG. 15 according to another embodiment of the present disclosure.

FIG. 18 is a diagram illustrating a table stored in a training manager of FIG. 1.

FIGS. 19A and 19B are timing diagrams illustrating an operation of a memory device based on an optimal preceding voltage level according to an embodiment of the present disclosure.

FIG. 20 is a flowchart illustrating a method of operating a memory system according to an embodiment of the present disclosure.

### DETAILED DESCRIPTION

Hereinafter, embodiments of the present disclosure will be described clearly and in detail to the extent that those skilled in the art can easily practice the present disclosure. Details such as detailed configurations and structures are provided merely to facilitate a general understanding of the embodiments of the present disclosure. Therefore, modifications of the embodiments described herein may be made by those skilled in the art without departing from the spirit and scope of the present disclosure. Moreover, descriptions of well-known functions and structures are omitted for clarity and simplicity. Components in the following drawings or detailed description may be connected with other components other than those shown in the drawings or described in the detailed description. The terms used in the text are terms defined in consideration of the functions of the present disclosure, and are not limited to these specific functions. Definitions of terms may be determined based on the details described in the detailed description. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

Components described with reference to terms such as a driver or a block used in the detailed description may be implemented in the form of software, hardware, or a combination thereof. Illustratively, the software may be machine code, firmware, embedded code, and application software. For example, the hardware may include an electrical circuit, an electronic circuit, a processor, a computer, an integrated circuit core, a pressure sensor, an inertial sensor, a micro electro mechanical system (MEMS), passive devices, or combinations thereof.

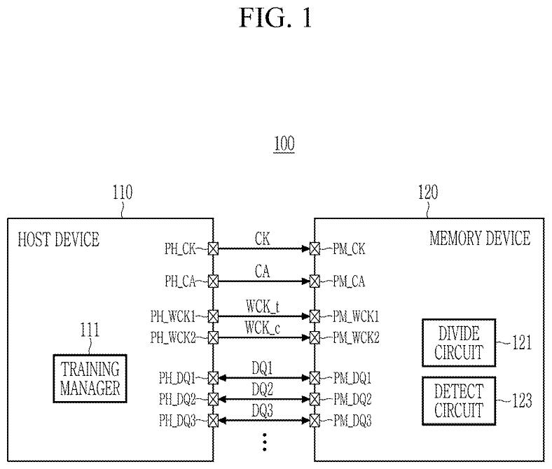

FIG. 1 is a block diagram illustrating a memory system according to an embodiment of the present disclosure. Referring to FIG. 1, a memory system 100 may include a host device 110 and a memory device 120. In the following, for brief simple description, it will be assumed that the host device 110 is a system on chip (SoC), the memory device 120 is a dynamic random access memory (DRAM), and the host device 110 and the memory device 120 are configured to communicate with each other based on a low power double data rate (LPDDR) interface. However, the scope of the present disclosure is not limited thereto.

The host device 110 may include a clock pin PH_CK, a command/address pin PH_CA, a first data clock pin PH_WCK1, a second data clock pin PH_WCK2, and first to third data pins PH_DQ1 to PH_DQ3.

The memory device 120 may include a clock pin PM_CK, a command/address pin PM_CA, a first data clock pin PM_WCK1, a second data clock pin PM_WCK2, and first to third data pins PM_DQ1 to PM_DQ3.

A clock pin PH_CK, a command/address pin PH_CA, a first data clock pin PH_WCK1, a second data clock pin PH_WCK2, and first to third data pins PH_DQ1 to PH_DQ3 may be connected to the clock pin PM_CK, the command/address pin PM_CA, the first data clock pin PM_WCK1, the second data clock pin PM_WCK2, and the first to third data pins PM_DQ1 to PM_DQ3 through different channels, respectively.

For more concise description, FIG. 1 illustrates that the host device 110 and the memory device 120 are each connected through three data pins, but the scope of the present disclosure is not limited thereto. For example, each of the host device 110 and the memory device 120 may include 16 data pins or 32 data pins.

The host device 110 may provide a clock signal CK to the memory device 120 through a channel connected to the clock pin PH_CK.

The host device 110 may provide the command/address signal CA to the memory device 120 through a channel connected to the command/address pin PH_CA.

The host device 110 may provide a data clock signal WCK_t to the memory device 120 through a channel connected to the first data clock pin PH_WCK1. The host device 110 may provide an inverted data clock signal WCK_c to the memory device 120 through a channel connected to the second data clock pin PH_WCK2.

The data clock signal WCK_t and the inverted data clock signal WCK_c may have phases complementary to each other. Hereinafter, for more concise description, the first data clock pin PM_WCK1 and the second data clock pin PM_WCK2 will be referred to together as data clock pins PM_WCK, and the data clock signal WCK_t and the inverted data clock signal WCK_c will be referred to together as data clock signals WCK. Hereinafter, for more concise description, an operation of the memory system 100 related to the data clock signal WCK_t will be representatively described. However, the scope of the present disclosure is not limited thereto.

The host device 110 may provide the first to third data signals DQ1 to DQ3 to the memory device 120, or may receive the first to third data signals DQ1 to DQ3 from the memory device 120, through channels connected to the first to third data pins PH_DQ1 to PH_DQ3.

The memory device 120 may include a divide circuit 121 and a detect circuit 123.

The divide circuit 121 may be configured to generate a plurality of internal data clock signals having different phases based on the data clock signal WCK_t and the inverted data clock signal WCK_c. Each of the plurality of internal data clock signals may be used for input/output operations of the memory device 120.

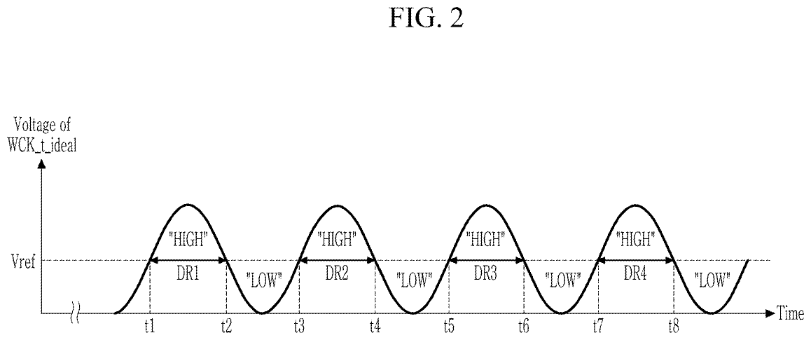

In some embodiments, an error may occur in the plurality of internal data clock signals generated by the divide circuit 121 due to an influence of a channel through which the data clock signal WCK_t and the inverted data clock signal WCK_c are transmitted. For example, when the voltage levels of the data clock signal WCK_t and the inverted data clock signal WCK_c do not change sufficiently, or the voltage levels of the data clock signal WCK_t and the inverted data clock signal WCK_c change excessively rapidly, the divide circuit 121 may be configured to operate in a meta-stability state. In this case, the logic level of the plurality of internal data clock signals generated by the divide circuit 121 may transition at a different time point than intended, and, thus, an error may occur in an input/output operation of the memory device 120. Example operations of the divide circuit 121 due to voltage level variations of the data clock signal WCK_t and the inverted data clock signal WCK_c will be described in more detail with reference to FIGS. 2 to 4 below.

In an embodiment, each of the data clock signal WCK_t and the inverted data clock signal WCK_c may include a ‘toggle period’ and a ‘preceding voltage period’. In this case, the toggle period may be referred to as a period in which the voltage levels of the data clock signal WCK_t and the inverted data clock signal WCK_c repeatedly rise and fall. The preceding voltage period may be referred to as a period in which the data clock signal WCK_t and the inverted data clock signal WCK_c maintain a constant voltage level prior to the toggle period.

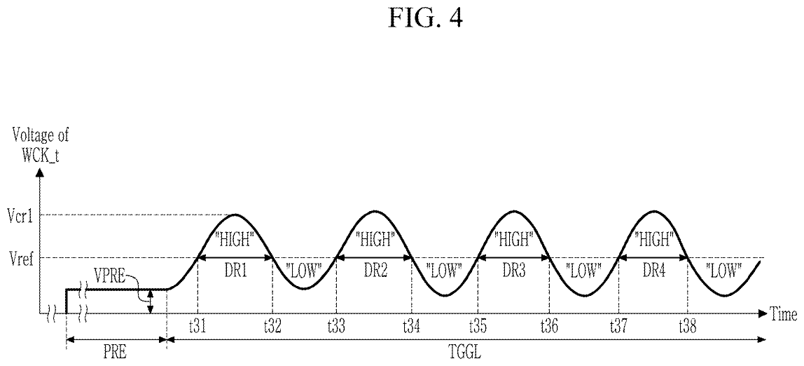

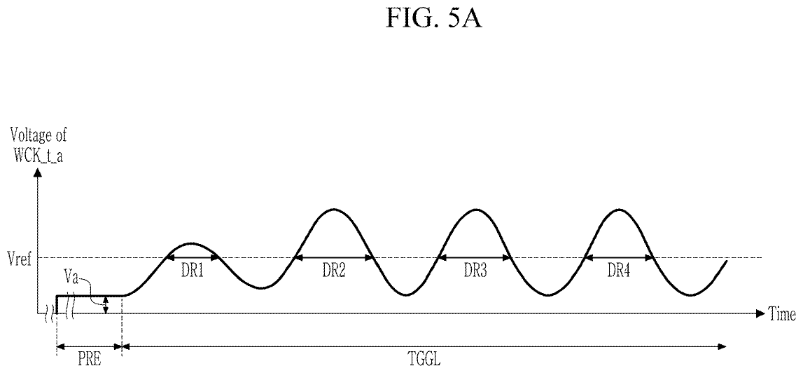

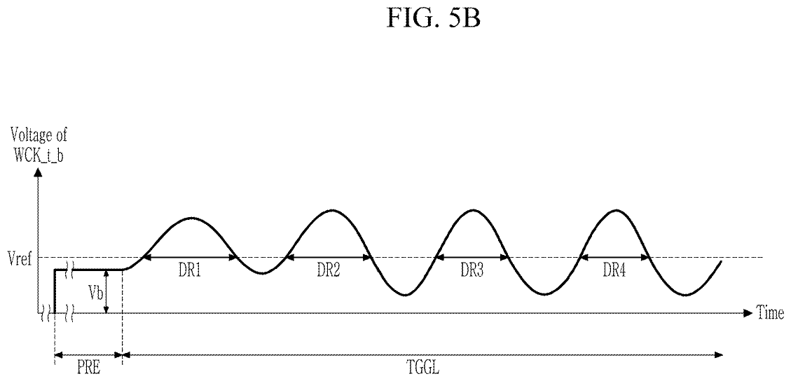

In an embodiment, when the data clock signal WCK_t and the inverted data clock signal WCK_c include a preceding voltage period, the divide circuit 121 may not operate in a meta-stability state. That is, when the data clock signal WCK_t and the inverted data clock signal WCK_c provided by the host device 110 have a specific voltage level during the preceding voltage period, an error may not occur in the internal data clock signals generated by the divide circuit 121. The operation of the divide circuit 121 according to the voltage level of the preceding voltage period will be described in detail with reference to FIGS. 4 and 5A and 5B below.

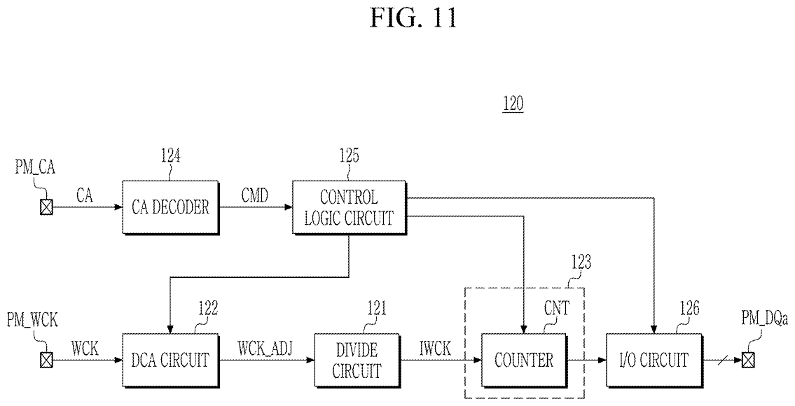

The detect circuit 123 may be configured to determine whether an error is included in an internal data clock signal generated from the divide circuit 121. That is, the detect circuit 123 may determine whether the internal data clock signal is normally generated based on the data clock signals WCK. The detect circuit 123 may be configured to generate feedback data based on the determination result. The specific configuration and operation of the detect circuit 123 will be described in more detail with reference to FIGS. 11 to 16 and FIGS. 17A to 17B below.

In an embodiment, the feedback data generated by the detect circuit 123 may be provided to the host device 110 through one of the first to third data signals DQ1 to DQ3. However, the scope of the present disclosure is not limited thereto.

The host device 110 may include a training manager 111. The training manager 111 may be configured to determine an optimal voltage level of the above-described preceding voltage period for preventing or reducing the risk of error occurrence of the internal data clock signals generated by the divide circuit 121. Hereinafter, for a more concise description, the optimal voltage level of the preceding voltage period will be referred to as an ‘optimal preceding voltage level’.

The training manager 111 may be configured to provide the data clock signals WCK having arbitrary voltage levels to the memory device 120 during the preceding voltage period. In this case, the divide circuit 121 may be configured to generate a plurality of internal data clock signals based on the data clock signals WCK. The detect circuit 123 may be configured to generate a feedback data by determining whether an error is included in the generated internal data clock signals. The feedback data may be returned to the training manager 111.

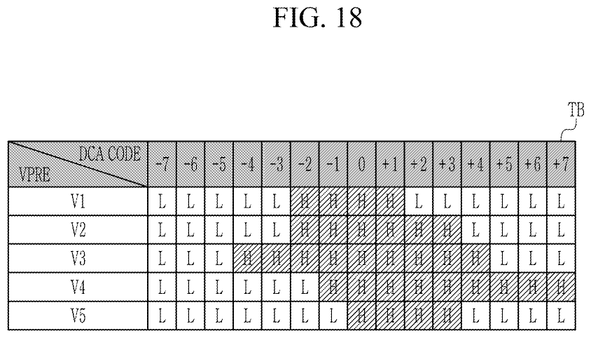

In this way, the training manager 111 may sequentially receive a plurality of feedback data by sequentially providing a plurality of data clock signals having different voltage levels to the memory device 120 during the preceding voltage period. In this case, the training manager 111 may determine the optimal preceding voltage level based on the plurality of received feedback data. A method in which the training manager 111 determines the optimal voltage level based on the plurality of feedback data will be described in detail with reference to FIG. 18 below.

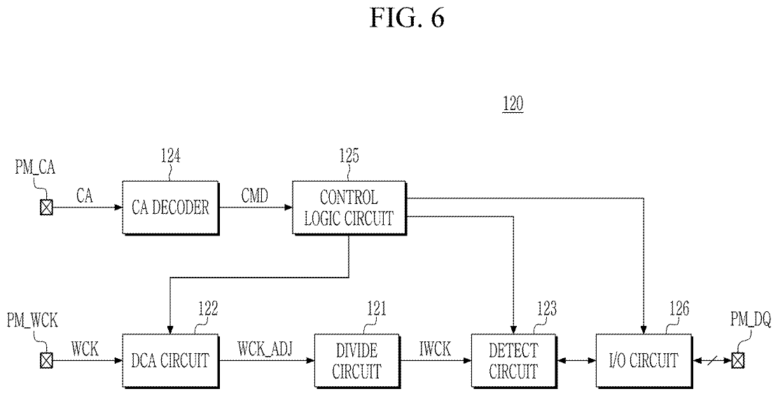

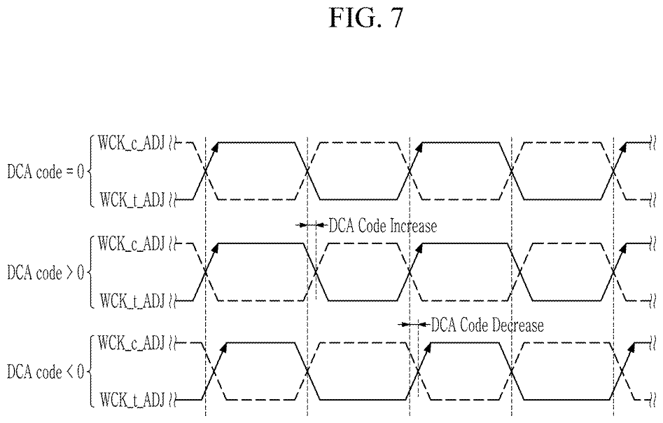

In an embodiment, a duty cycle adjuster (DCA) circuit may be further included between the data clock pins PM_WCK and the divide circuit 121. The DCA circuit may be configured to adjust the duty cycles of the data clock signal WCK_t and the inverted data clock signal WCK_c received through the data clock pins PM_WCK. For example, the DCA circuit may increase or decrease the duty cycle of the data clock signals WCK in response to the set DCA code. In this case, the divide circuit 121 may be configured to receive a data clock signal having the adjusted duty cycle from the DCA circuit. However, the scope of the present disclosure is not limited thereto, and an embodiment in which the divide circuit 121 operates based on the data clock signals WCK whose duty cycle is not adjusted will be described as a representative example. Specific functions of the DCA circuit will be described in detail with reference to FIGS. 6 and 7 below.

FIG. 2 is a diagram illustrating an ideal voltage level of a data clock signal provided to the memory device of FIG. 1.

Referring to FIGS. 1 and 2, a voltage level of a data clock signal WCK_t_ideal may toggle at regular time intervals. For example, all intervals between a first time point t1 to an eighth time point t8 may be the same.

The data clock signal WCK_t_ideal may have a voltage level higher than a reference voltage Vref between the first time point t1 and a second time point t2 and may have a voltage level lower than a reference voltage Vref between the second time point t2 and the third time point t3. In this case, the divide circuit 121 may be configured to recognize that the data clock signal WCK_t_ideal is a logic high between the first time point t1 and the second time point t2, and recognize that the data clock signal WCK_t_ideal is a logic low between the second time point t2 and the third time point t3.

Similarly, the divide circuit 121 may be configured to recognize that the data clock signal WCK_t_ideal is a logic high HIGH in time periods between the third time point t3 and the fourth time point t4, between the fifth time point t5 and the sixth time point t6, and between the seventh time point t7 and the eighth time point t8, and may be configured to recognize that the data clock signal WCK_t_ideal is a logic low LOW between a fourth time point t4 and a fifth time point t5, between a sixth time point t6 and a seventh time point t7, and after an eighth time point t8.

In an embodiment, the reference voltage Vref may be referred to as a voltage at which the divide circuit 121 determines the logic level of the data clock signal WCK_t_ideal.

The duty rate recognized by the divide circuit 121 for a time period in which the voltage level of the data clock signal WCK_t_ideal first rises and falls may be referred to as a first duty rate DR1. For example, the first duty rate DR1 refers to a rate of time intervals of the first to second time points t1 to t2 among time periods in which the voltage level of the data clock signal (i.e., WCK_t_ideal) first rises and falls. Similarly, the duty rate recognized by the divide circuit 121 for a time period in which the voltage level of the data clock signal WCK_t_ideal second rises and falls may be referred to as a second duty rate DR2. Third and fourth duty rates DR3 and DR4 are similar to descriptions of the first and second duty rates DR1 and DR2 described above, and therefore, detailed descriptions thereof will be omitted.

In the case of FIG. 2, all of the first to fourth duty rates DR1 to DR4 may be 50%. In this case, according to the embodiment of FIG. 2, the divide circuit 121 may accurately recognize the logic level of the data clock signal WCK_t_ideal. That is, the divide circuit 121 may not operate in a meta-stability state. Accordingly, an error may not be included in the internal data clock signal generated by the divide circuit 121 based on the data clock signal WCK_t_ideal.

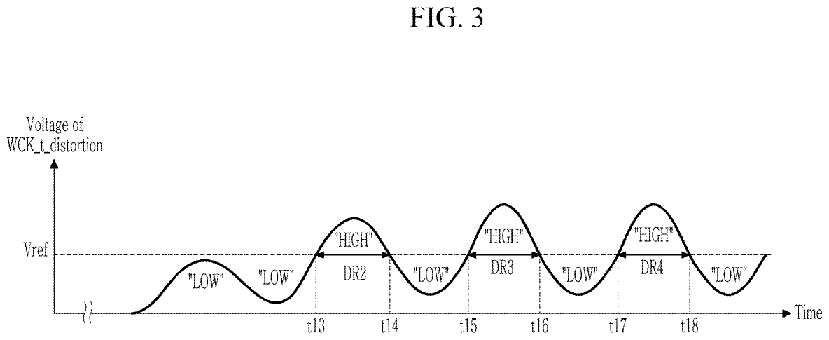

FIG. 3 is a diagram illustrating a voltage level of a data clock signal provided to the memory device of FIG. 1 according to some embodiments of the disclosure. Referring to FIGS. 1 to 3, distortion may occur in a data clock signal WCK_t_distortion received by the memory device 120 due to an influence of a channel connected between the host device 110 and the memory device 120. For example, the data clock signal WCK_t_distortion received by the memory device 120 may include distortion due to inter symbol interference (ISI). In this case, it may be difficult for the divide circuit 121 to accurately recognize the logic level of the data clock signal WCK_t_distortion until a sufficient time elapses after the data clock signal WCK_t_distortion starts toggling.

For example, the voltage level of the data clock signal WCK_t_distortion may not rise above the reference voltage Vref until a thirteenth time point t13. In this case, the divide circuit 121 may recognize that the data clock signal WCK_t_distortion is a logic low LOW before the thirteenth time point t13. That is, even though the voltage level of the data clock signal WCK_t_distortion sequentially rises, falls, and rises until the thirteenth time point t13, the divide circuit 121 may not detect the logic level transition of the data clock signal WCK_t_distortion until the thirteenth time point t13. In this case, an error may occur in the operation of the memory device 120 based on the internal data clock signal generated by the divide circuit 121.

Also, unlike what was previously described with reference to FIG. 2, a time interval in which the voltage level of the data clock signal WCK_t_distortion toggles may not be constant. That is, the intervals between the thirteenth to eighteenth time points t13 to t18 may be different from each other. For example, in response to the data clock signal WCK_t_distortion, the divide circuit 121 may recognize the first duty rate DR1 as ‘0%’, and recognize that the second to fourth duty rates DR2 to DR4 are different. That is, each of the first to fourth duty rates DR1 to DR4 may be greater than 50% or less than 50%.

When each of the first to fourth duty rates DR1 to DR4 is excessively greater than 50% or excessively less than 50%, it may be difficult for the divide circuit 121 to accurately detect the logic level transition of the data clock signal WCK_t_distortion. For example, when each of the first to fourth duty rates DR1 to DR4 is excessively greater than 50% or excessively less than 50%, the divide circuit 121 may operate in the meta-stability state. In this case, an error may occur in the operation of the memory device 120 based on the internal data clock signal generated by the divide circuit 121.

FIG. 4 is a diagram illustrating a voltage level of a data clock signal according to an embodiment of the present disclosure. Referring to FIGS. 1 to 4, the data clock signal WCK_t may include a preceding voltage period (PRE) and a toggle period (TGGL).

During the preceding voltage period PRE, the data clock signal WCK_t may maintain a constant voltage level. For example, the voltage level of the data clock signal WCK_t during the preceding voltage period PRE may be a preceding voltage level VPRE.

In an embodiment, the preceding voltage level VPRE, at which the logic level transition of the data clock signal WCK_t is accurately detected by the divide circuit 121, may be referred to as an optimal preceding voltage level. An optimal preceding voltage level may be determined by the training manager 111. An example method in which the optimal preceding voltage level is determined according to some embodiments of the disclosure will be described in detail with reference to the following drawings.

The preceding voltage period PRE may be consecutive with the toggle period TGGL. For example, an end point of the preceding voltage period PRE may be the same as a start point of the toggle period TGGL. In this case, the voltage level distortion occurring in the toggle period TGGL may be reduced or minimized by the voltage level of the preceding voltage period PRE. For example, the voltage level of the preceding voltage period PRE may serve as a de-emphasis voltage for the toggle period TGGL. However, the scope of the present disclosure is not limited thereto, and the voltage level of the preceding voltage period PRE may serve as a pre-shoot voltage for the toggle period TGGL.

During the toggle period TGGL, the voltage level of the data clock signal WCK_t may repeatedly rise and fall. For example, the voltage level of the data clock signal WCK_t may be higher than the reference voltage Vref of the data clock signal WCK_t between thirty-first to thirty-second time points t31 to t32, thirty-third to thirty-fourth time points t33 to t34, thirty-fifth to thirty-sixth time points t35 to t36, thirty-seventh to thirty-eighth time points t37 to t38. The voltage level of the data clock signal WCK_t may be lower than the reference voltage Vref of the data clock signal WCK_t after the thirty-second to thirty-third time points t32 to t33, thirty-fourth to thirty-fifth time points t34 to t35, thirty-sixth to thirty-seventh time points t36 to t37, and thirty-eighth time point t38.

In an embodiment, unlike what has been described with reference to FIG. 3, when the preceding voltage level VPRE has an appropriate size (e.g., a size of an optimal preceding voltage level), the voltage level may rise sufficiently higher than the reference voltage Vref even when the voltage level of the data clock signal WCK_t first rises. For example, the voltage level of the data clock signal WCK_t may rise to a first crest voltage Vcr1 between the thirty-first to thirty-second time points t31 to t32. In this case, the first crest voltage Vor1 may be a size similar to the highest voltage level of the data clock signal WCK_t between the thirty-third to thirty-fourth time points t33 to t34, or the highest voltage level of the data clock signal WCK_t between the thirty-fifth to thirty-sixth t35 and t36.

In addition, when the preceding voltage level VPRE has an appropriate size (e.g., size similar to the optimal preceding voltage level), each of the first to fourth duty rates DR1 to DR4 may have a value similar to 50%. In this case, the divide circuit 121 may accurately recognize the logic level of the data clock signal WCK_t.

That is, according to an embodiment of the present disclosure, the distortion of the data clock signal WCK_t due to the inter symbol interference (ISI) may be reduced or minimized. In this case, the divide circuit 121 may not operate in the meta-stability state. Therefore, according to an embodiment of the present disclosure, the error of the internal data clock signal may be reduced or minimized.

In an embodiment, the first to fourth duty rates DR1 to DR4 may vary according to the size of the preceding voltage level VPRE. For example, each of the first to fourth duty rates DR1 to DR4 may increase or decrease according to the size of the preceding voltage level VPRE. Accordingly, depending on the size of the preceding voltage level VPRE, whether the divide circuit 121 operates in the meta-stability state may vary. The relationship between the magnitude of the preceding voltage level VPRE and the first to fourth duty rates DR1 to DR4 will be described in more detail with reference to FIGS. 5A to 5B below.

In an embodiment, the optimal preceding voltage level may be less than the reference voltage Vref. However, the scope of the present disclosure is not limited thereto.

FIGS. 5A to 5B are diagrams illustrating the relationship between a magnitude of a preceding voltage level and first to fourth duty ratios of FIG. 4.

First, referring to FIGS. 1 to 4 and FIG. 5A, the preceding voltage level VPRE may be ‘Va’ lower than the optimal preceding voltage level. In this case, the voltage level of the data clock signal WCK_t_a may not rise to a level sufficiently higher than the reference voltage Vref. In this case, the first duty rate DR1 may have a value less than 50%.

That is, the lower the preceding voltage level VPRE, the smaller the first duty rate DR1 may be. In this case, the divide circuit 121 may operate in the meta-stability state. Accordingly, the divide circuit 121 may not accurately detect a logic level transition when the voltage level of the data clock signal WCK_t_a first rises.

On the other hand, referring to FIGS. 1 to 4 and FIG. 5B, the preceding voltage level VPRE may be ‘Vb’ greater than the optimal preceding voltage level. In this case, after the voltage level of the data clock signal WCK_t_b first rises, the time for the data clock signal WCK_t_b to maintain the voltage level higher than the reference voltage Vref may be excessively long. In this case, the first duty rate DR1 may have a value greater than 50%.

That is, as the magnitude of the preceding voltage level VPRE increases, the value of the first duty rate DR1 may increase. Accordingly, the divide circuit 121 may operate in the meta-stability state. In this case, it may be difficult for the divide circuit 121 to accurately distinguish a period in which the voltage level of the data clock signal WCK_t_b first rises and a period in which the voltage level rises second. That is, it may be difficult for the divide circuit 121 to clearly distinguish the time at which the data clock signal WCK_t_b transitions to logic low.

That is, according to an embodiment of the present disclosure, when the magnitude of the preceding voltage level VPRE is excessively large or excessively small, an error may occur in the logic level of the internal data clock signal generated by the divide circuit 121. On the other hand, when the preceding voltage level VPRE is the optimal preceding voltage level, an error may not occur in the logic level of the internal data clock signal generated by the divide circuit 121.

In an embodiment, the optimal preceding voltage level may vary according to a channel connected between the host device 110 and the memory device 120. For example, even if a plurality of memory devices are produced through the same process, the optimal preceding voltage level may vary depending on the type of the host device 110 to which each of the plurality of memory devices is connected. In addition, the optimal preceding voltage level may vary depending on process distribution of the host device 110 and the memory device 120.

The training manager 111 according to an embodiment of the present disclosure may perform a training operation for determining the above-described optimal preceding voltage level. That is, regardless of the channel connected between the host device 110 and the memory device 120 and the process distribution of the host device 110 and the memory device 120, the training manager 111 may be configured to determine an optimal preceding voltage level for the memory system 100. Therefore, according to an embodiment of the present disclosure, the divide circuit 121 may not operate in the meta-stability state, and the error in the logic level of the internal data clock signal used inside the memory device 120 may be minimized.

FIG. 6 is a block diagram illustrating a configuration of a memory device according to an embodiment of the present disclosure. Referring to FIGS. 1 to 6, the memory device 120 may include a divide circuit 121, a DCA circuit 122, a detect circuit 123, a command/address (CA) decoder 124, a control logic circuit 125, and an input/output (I/O) circuit 126. Detailed descriptions of the above-described divide circuit 121 and detect circuit 123 will be omitted.

The DCA circuit 122 may be connected between the data clock pins PM_WCK and the divide circuit 121. The DCA circuit 122 may receive the data clock signals WCK.

The DCA circuit 122 may be configured to operate based on the control of the control logic circuit 125. For example, the DCA circuit 122 may be set based on the DCA code provided from a control logic circuit 125. In this case, the DCA circuit 122 may be configured to adjust the duty cycles of the data clock signal WCK_t and the inverted data clock signal WCK_c based on the set DCA code.

In an embodiment, the DCA code may be an integer equal to or greater than ‘−7’ and equal to or less than ‘7’. However, the scope of the present disclosure is not limited thereto.

In an embodiment, the DCA code may be controlled in response to a mode register write (MRW) command issued from the host device 110.

The DCA circuit 122 may be configured to output the adjusted data clock signals WCK_ADJ. For example, the adjusted data clock signals WCK_ADJ may include a data clock signal WCK_t_ADJ whose duty cycle is adjusted based on the set DCA code, and include an inverted data clock signal WCK_c_ADJ whose duty cycle is adjusted based on the set DCA code. The logic level transition of the adjusted data clock signals WCK_ADJ according to the value of the DCA code will be described in detail with reference to FIG. 7 below.

In an embodiment, when the DCA code is ‘0’, the adjusted data clock signals WCK_ADJ may be the same as the data clock signals WCK.

The divide circuit 121 may be configured to generate an internal data clock signal IWCK by receiving the adjusted data clock signals WCK_ADJ. For example, the divide circuit 121 may be configured to generate four clock signals having the same frequency and different phases based on the adjusted data clock signals WCK_ADJ. Hereinafter, for a more concise description, the internal data clock signal IWCK may be referred to as a clock signal having the fastest phase among the clock signals generated by the divide circuit 121. However, the scope of the present disclosure is not limited to what the divide circuit 121 generates.

In an embodiment, the clock signals generated by the divide circuit 121 may be used for the input/output operation of the memory device 120. For example, the clock signals generated by the divide circuit 121 may be provided to the input/output circuit 126. However, the scope of the present disclosure is not limited thereto.

In an embodiment, the frequency of the internal data clock signal IWCK may be half of the frequency of the adjusted data clock signals WCK_ADJ.

In an embodiment, the frequency of the internal data clock signal IWCK may be half of the frequency of the data clock signals WCK.

The detect circuit 123 may be configured to receive the internal data clock signal IWCK. The detect circuit 123 may be configured to determine whether an error is included in the internal data clock signal IWCK. A specific method for the detect circuit 123 to determine whether an error is included in the internal data clock signal IWCK will be described in detail with reference to FIGS. 11 to 16 and FIGS. 17A to 17B.

The detect circuit 123 may be configured to generate feedback data based on the determination result. The detect circuit 123 may be configured to provide feedback data to the host device 110 through the input/output circuit 126. That is, the input/output circuit 126 may be configured to output the feedback data provided from the detect circuit 123 to the host device 110 through a data pin PM_DQ.

The command/address decoder 124 may be configured to receive the command/address signals CA provided from the command/address pin PM_CA. The command/address decoder 124 may be configured to decode the command/address signals CA into a command CMD and an address.

In an embodiment, the command CMD may be a read command, a write command, a DCA command for changing the DCA code set for the DCA circuit 122, a preceding voltage training command to provide the data clock signals to the memory device to generate the feedback data, or a data clock synchronize command (WCK synchronize command). However, the scope of the present disclosure is not limited thereto.

The control logic circuit 125 may be configured to receive the command CMD. The control logic circuit 125 may be configured to control the operations of each component of the memory device 120 based on the command CMD. For example, the control logic circuit 125 may be configured to control the operating timing of each component of the memory device 120 based on the command CMD.

In an embodiment, the host device 110 may be configured to change the DCA code set for the DCA circuit 122 through the DCA command. For example, training manager 111 may issue the command/address signal (CA) indicating the DCA command.

In an embodiment, the training manager 111 may be configured to sweep different DCA codes and sequentially output the data clock signals having the same preceding voltage level. In this case, the memory device 120 may sequentially output the feedback data generated based on different DCA codes to the host device 110. The training manager 111 may be configured to determine whether the preceding voltage level is appropriate based on the feedback data. A method in which the training manager 111 determines the optimal voltage level based on the plurality of feedback data will be described in detail with reference to FIG. 18 below.

FIG. 7 is a diagram illustrating a DCA code and logic levels of adjusted data clock signals according to an embodiment of the disclosure. Referring to FIGS. 1, 6, and 7, the adjusted data clock signals WCK_ADJ may include an adjusted data clock signal WCK_t_ADJ and an adjusted inverted data clock signal WCK_c_ADJ.

First, when the DCA code set for the DCA circuit 122 is ‘0’, the adjusted data clock signals WCK_ADJ may be the same as the data clock signals WCK. In this case, the length of the period in which the adjusted data clock signal WCK_t_ADJ is a logic high may be equal to the length of the period in which the adjusted inverted data clock signal WCK_c_ADJ is a logic high.

When the DCA code set for the DCA circuit 122 is greater than ‘0’, the DCA circuit 122 may increase the length of the period in which the data clock signal WCK_t is a logic high. In this case, the length of the period in which the adjusted data clock signal WCK_t_ADJ is a logic high may be longer than the length of the period in which the adjusted inverted data clock signal WCK_c_ADJ is a logic high.

When the DCA code set for the DCA circuit 122 is less than ‘0’, the DCA circuit 122 may increase the length of the period in which the inverted data clock signal WCK_c is a logic high. In this case, the length of the period in which the adjusted data clock signal WCK_t_ADJ is a logic high may be shorter than the length of the period in which the adjusted inverted data clock signal WCK_c_ADJ is a logic high.

That is, according to an embodiment of the present disclosure, because the DCA code set for the DCA circuit 122 may change in response to the control of the training manager 111, the time at which the voltage level of the adjusted data clock signal WCK_ADJ provided to the divide circuit 121 changes may vary. In this case, whether the divide circuit 121 operates in the meta-stability state may vary in response to the adjusted data clock signal WCK_ADJ.

Accordingly, according to an embodiment of the present disclosure, the time at which the logic level of the internal data clock signal IWCK changes may vary based on the set DCA codes. The operation of the detect circuit 123 according to the time at which the logic level of the internal data clock signal IWCK changes will be described in detail with reference to the following drawings.

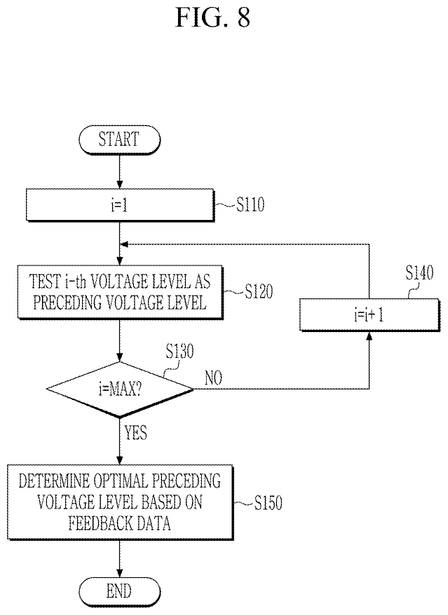

FIG. 8 is a flowchart illustrating an operation of the memory system of FIG. 1 according to an embodiment of the disclosure. Referring to FIGS. 1 to 8, in operation S110, variable ‘i’ may be set to ‘1’. The variable ‘i’ is only used to describe a repetitive operation of the memory system 100 and does not limit the scope of the present disclosure.

In operation S120, the memory system 100 may test an i-th voltage level as the preceding voltage level VPRE. For example, the host device 110 may output the data clock signal WCK_t whose preceding voltage level VPRE is the i-th voltage level. In this case, the memory device 120 may return the feedback data to the host device 110.

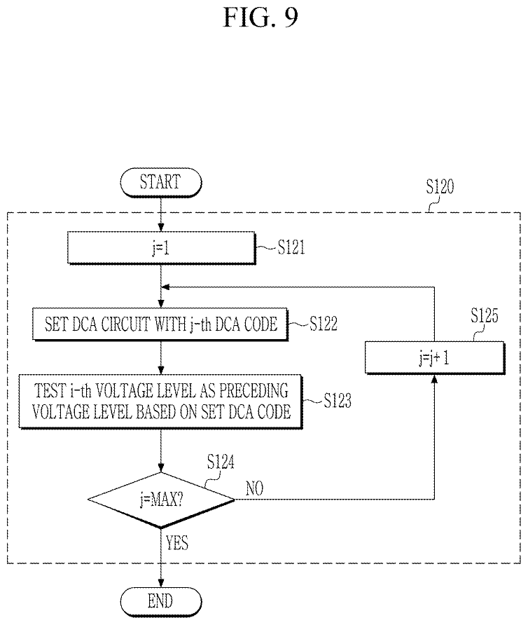

In an embodiment, the memory system 100 may test the i-th voltage level as the preceding voltage level VPRE while sweeping one or more DCA codes. In this case, the memory device 120 may return a plurality of feedback data for each of the different DCA codes to the host device 110. A specific operation associated with operation S120 performed while sweeping one or more DCA codes will be described in detail with reference to FIG. 9 below.

In operation S130, the memory system 100 may determine whether variable ‘i’ is maximum. For example, the host device 110 may determine whether all voltage levels that may be generated as the voltage levels of the data clock signals WCK have been tested as the preceding voltage level VPRE.

In an embodiment, when the host device 110 determines that an untested voltage remains as the preceding voltage level VPRE, the following operation S140 may be performed.

In an embodiment, when the host device 110 determines that all voltage levels are tested as the preceding voltage level VPRE, the following operation S150 may be performed.

In operation S140, variable ‘i’ may be increased by ‘1’. Thereafter, the above-described operation S120 may be repeatedly performed. In this way, the host device 110 may sequentially test different voltage levels as the preceding voltage level VPRE. In this case, the memory device 120 may sequentially provide the feedback data for each of the different voltage levels to the host device 110.

In operation S150, the memory system 100 may determine an optimal preceding voltage level based on the feedback data. For example, the training manager 111 may determine the optimal preceding voltage level based on the plurality of feedback data provided from the memory device 120 through the repeatedly performed operation S120. In this case, the optimal preceding voltage level may be one of the voltage levels tested in the repeatedly performed operation S120. The operation of the memory system 100 in operation S150 will be described with reference to FIG. 18 below.

FIG. 9 is a flowchart illustrating operation S120 of FIG. 8 in more detail according to an embodiment of the disclosure. Referring to FIGS. 1 to 9, operation S120 may include the following operations S121 to S125.

In operation S121, variable ‘j’ may be set to ‘1’. The variable ‘j’ is only used to describe a repetitive operation of the memory system 100 and does not limit the scope of the present disclosure.

In operation S122, the memory system 100 may set the DCA circuit 122 to a j-th DCA code. For example, the host device 110 may transmit a DCA command requesting to change the DCA code for the DCA circuit 122 to the memory device 120.

In operation S123, the memory system 100 may test the i-th voltage level as the preceding voltage level based on the DCA code set in step S122. In this case, the memory device 120 may return the feedback data to the host device 110.

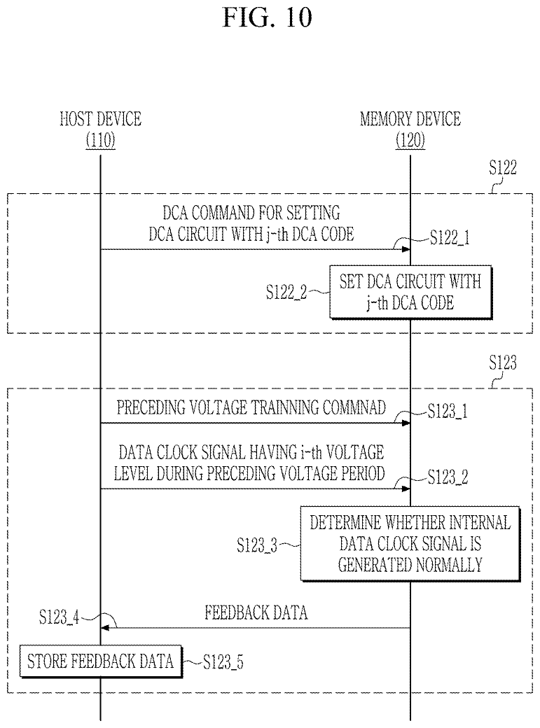

Operations of the memory system 100 in operations S122 and S123 will be described in detail with reference to FIG. 10 below.

In operation S124, the memory system 100 may determine whether the variable ‘j’ is maximum. That is, the host device 110 may determine whether the i-th voltage level has been tested as the preceding voltage level VPRE based on all of DCA codes. For example, the host device 110 may determine whether all the feedback data has been received, which correspond to the cases where from “the preceding voltage level VPRE is the i-th voltage level and the DCA code is set to ‘+7’” to “the preceding voltage level VPRE is the i-th voltage level and the DCA code is set to ‘−7’”.

In an embodiment, when the host device 110 determines that the i-th voltage level has not been tested as the preceding voltage level based on all the DCA codes, operation S120 may end. Hereinafter, for a more concise description, an embodiment in which operation S120 ends only when all the feedback data where the DCA code is ‘−7’ to ‘+7’ is received will be described as a representative example. However, the scope of the present disclosure is not limited thereto. For example, even if only feedback data for some DCA codes from ‘−7’ to ‘+7’ is provided to the host device 110, operation S120 may end.

In an embodiment, when the host device 110 determines that the i-th voltage level has been tested as the preceding voltage level VPRE based on all DCA codes, the following operation S125 may be performed. That is, when the host device 110 determines that feedback data corresponding to some DCA codes is not received, the following operation S125 may be performed.

In operation S125, the variable ‘j’ may be increased by ‘1’. Thereafter, the above-described operation S122 may be repeatedly performed. In this way, the host device 110 may receive a plurality of feedback data for one preceding voltage level VPRE by sweeping one or more DCA codes. In this case, the plurality of feedback data may correspond to different DCA codes from each other and may correspond to the same preceding voltage level VPRE.

FIG. 10 is a flowchart illustrating operations S122 to S123 of FIG. 9 in more detail according to an embodiment of the disclosure. Referring to FIGS. 1 to 10, operation S122 may include the following operations S122_1 to S122_2. Operation S123 may include the following operations S123_1 to S123_4.

In operation S122_1, the host device 110 may transmit a DCA command for configuring the DCA circuit 122 with the j-th DCA code to the memory device 120.

In an embodiment, the DCA command may be implemented as a mode register write (MRW) command.

In operation S122_2, the memory device 120 may set the DCA circuit 122 to the j-th DCA code in response to the DCA command.

In an embodiment, the control logic circuit 125 may set OP[0] to OP[7] of mode register #30 (MR30) based on the j-th DCA code in response to the DCA command.

In operation S123_1, the host device 110 may transmit a preceding voltage training command to the memory device 120.

In an embodiment, the preceding voltage training command may be received over two cycles of the clock signal CK and may be provided to the memory device 120. However, the scope of the present disclosure is not limited thereto.

In operation S123_2, the host device 110 may provide the data clock signal WCK_t having the i-th voltage level to the memory device 120 during the preceding voltage period PRE.

In operation S123_3, the memory device 120 may determine whether the internal data clock signal IWCK is normally generated in response to the data clock signal WCK_t. For example, the memory device 120 may determine whether an error is included in the internal data clock signal IWCK as the divide circuit 121 operates in the meta-stability state. In this case, the detect circuit 123 may generate the feedback data based on the determination result.

In an embodiment, when the internal data clock signal IWCK is normally generated, the logic level transitions of the internal data clock signal IWCK may correspond to all rising edges of the data clock signal WCK_t, respectively. That is, the detect circuit 123 may determine whether the logic level of the internal data clock signal IWCK transitions in response to all rising edges of the data clock signal WCK_t, and thus, may determine whether the internal data clock signal IWCK is normally generated. However, the scope of the present disclosure is not limited thereto.

In operation S123_4, the memory device 120 may provide the feedback data to the host device 110. In this case, the feedback data may correspond to the j-th DCA code set in operation S122_1 and the i-th voltage level provided in operation S123_2.

In an embodiment, when it is determined that the divide circuit 121 does not include an error in the internal data clock signal IWCK, the feedback data may be a logic high. On the other hand, when it is determined that the internal data clock signal IWCK includes an error (i.e., when it is determined that the divide circuit 121 operates in the meta-stability state), the feedback data may be a logic low. However, the scope of the present disclosure is not limited thereto.

In operation S123_5, the host device 110 may store the received feedback data. For example, the host device 110 may store the received feedback data in a table form. That is, the host device 110 may store the logical level of feedback data according to the combination of the preceding voltage level VPRE and the DCA code in the form of the table. A table of feedback data stored and managed by the host device 110 will be described in detail with reference to FIG. 18 below.

FIG. 11 is a block diagram illustrating the memory device of FIG. 6 implemented according to an embodiment. Referring to FIGS. 1 to 11, the memory device 120 may include the divide circuit 121, the DCA circuit 122, the detect circuit 123, the CA decoder 124, the control logic circuit 125, and the input/output circuit 126. The configuration and operation of the divide circuit 121, the DCA circuit 122, the CA decoder 124, the control logic circuit 125, and the input/output circuit 126 have been described with reference to FIG. 6, and therefore, detailed descriptions thereof will be omitted.

The detect circuit 123 may include a counter CNT. The counter CNT may be configured to count rising edges of the internal data clock signal IWCK. For example, the counter CNT may increase the count value by ‘1’ in response to the rising edge of the internal data clock signal IWCK. For a more concise description, an embodiment in which the counter CNT operates in response to the rising edge of the internal data clock signal IWCK will be described as a representative example. However, the scope of the present disclosure is not limited thereto, and the counter CNT may be configured to operate in response to a falling edge of the internal data clock signal IWCK.

The counter CNT may be configured to generate the feedback data based on the count value after the toggle period TGGL of the data clock signal WCK_t ends. For example, when the count value does not reach a pre-determined value after the toggle period TGGL ends, the counter CNT may generate feedback data indicating logic low. On the other hand, when the count value reaches the predetermined value after the toggle period TGGL ends, the counter CNT may generate feedback data indicating logic high.

In an embodiment, the predetermined value may be a value determined between the host device 110 and the memory device 120 according to the number of rising edges of the data clock signal WCK_t during the toggle period TGGL. The relationship between the number of rising edges of the data clock signal WCK_t during the toggle period TGGL and the predetermined value will be described in more detail below.

In an embodiment, the counter CNT may be configured to output the feedback data to the host device 110 after a write leveling output delay (tWLO) elapses after the toggle period TGGL ends. However, the scope of the present disclosure is not limited thereto.

In an embodiment, the frequency of the internal data clock signal IWCK may be half of that of the data clock signal WCK_t. In this case, when the logic level of the data clock signal WCK_t rises twice, the logic level of the internal data clock signal IWCK may rise once. Accordingly, the number of rising edges of the internal data clock signal IWCK may be determined according to the number of rising edges of the data clock signal WCK_t transmitted by the host device 110.

In an embodiment, when the number of rising edges of the data clock signal WCK_t transmitted by the host device 110 is ‘2N−1’ (wherein N is a natural number) and the internal data clock signal IWCK is normally generated, the number of rising edges of the internal data clock signal IWCK may be N. That is, according to an embodiment of the present disclosure, it may be determined whether the divide circuit 121 operates in the meta-stability state according to whether the count value is ‘N’. Accordingly, a predetermined value corresponding to the logic level of the feedback data may be ‘N’.

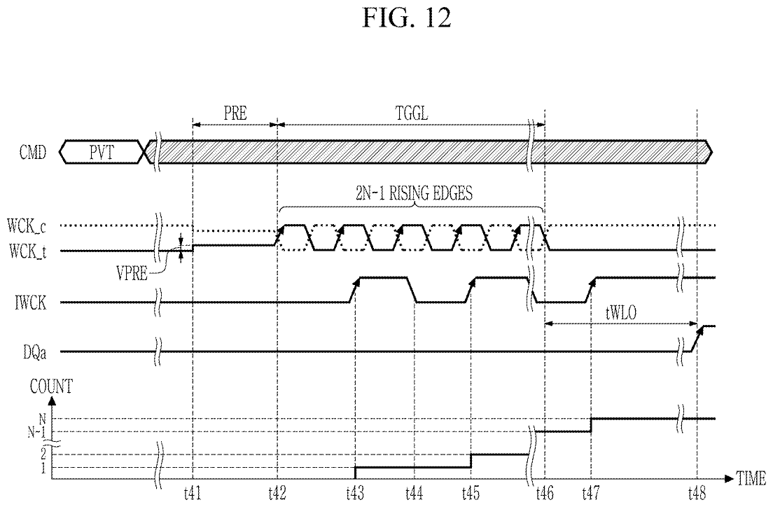

In an embodiment, when the divide circuit 121 does not accurately recognize the rising edge of the data clock signal WCK_t, the number of rising edges of the internal data clock signal IWCK may be less than ‘N’. In this case, the feedback data indicating logic low may be provided to the host device 110. The relationship between the number of rising edges of the internal data clock signal IWCK and the feedback data will be described in more detail with reference to FIGS. 12 to 14 below.

In an embodiment, the count value of the counter CNT may be reset based on the control of the control logic circuit 125. For example, the control logic circuit 125 may be configured to reset the count value of the counter CNT in response to the preceding voltage training command. More specifically, the control logic circuit 125 may be configured to reset the count value of the counter CNT after the preceding voltage training command is received and before the preceding voltage period PRE starts. However, the scope of the present disclosure is not limited thereto. For example, the control logic circuit 125 may reset the count value of the counter CNT after the preceding voltage training command is received and before the toggle period TGGL starts.

The input/output circuit 126 may be configured to provide the feedback data provided from the counter CNT to a first data pin PM_DQa. The first data pin PM_DQa may be one of the plurality of data pins described above with reference to FIG. 1. Hereinafter, a signal transmitted to the host device 110 through the first data pin PM_DQa will be referred to as a first data signal DQa. In this case, the first data signal DQa may indicate the feedback data provided from the counter CNT.

FIG. 12 is a timing diagram illustrating an operation of the memory device of FIG. 11 according to an embodiment. Hereinafter, the embodiment in which the memory device 120 outputs the feedback data indicating logic high to the host device 110 will be described with reference to FIG. 12.

Referring to FIGS. 1 to 12, the memory device 120 may receive a preceding voltage training command PVT from the host device 110. For example, the memory device 120 may receive the command/address signals CA indicating the preceding voltage training command PVT from the host device 110.

After receiving the preceding voltage training command PVT, the memory device 120 may receive the data clock signals WCK including the preceding voltage period PRE and the toggle period TGGL from the host device 110. In this case, the preceding voltage period PRE may correspond to a time period between a forty-first time point t41 and a forty-second time point t42. The toggle period TGGL may correspond to a time period between the forty-second time point t42 and a forty-sixth time point t46.

In an embodiment, the end point of the preceding voltage period PRE and the start time of the toggle period TGGL may be same. For example, the end point of the preceding voltage period PRE and the start time of the toggle period TGGL may be the forty-second time point t42.

A voltage level during the preceding voltage period PRE of the data clock signals WCK may be different from a voltage level before the forty-first time point t41 of the data clock signals WCK. For example, the voltage level of the time period between the forty-first time point t41 and the forty-second time point t42 of the data clock signal WCK_t may be higher than the voltage level before the forty-first time point t41. For example, the voltage level of the time period between the forty-first time point t41 and the forty-second time point t42 of the data clock signal WCK_t may be higher than the voltage level before the forty-first time point t41 as the preceding voltage level VPRE. However, the scope of the present disclosure is not limited thereto.

Similarly, the voltage level of the time period between the forty-first time point t41 and the forty-second time point t42 of the inverted data clock signal WCK_c may be lower than the voltage level before the forty-first time point t41. For example, the voltage level of the time period between the forty-first time point t41 and the forty-second time point t42 of the inverted data clock signal WCK_c may be lower than the voltage level before the forty-first time point t41 by the preceding voltage level VPRE. However, the scope of the present disclosure is not limited thereto.

In an embodiment, the training manager 111 may determine the preceding voltage level VPRE. For example, the training manager 111 may determine the i-th voltage level (specifically, the voltage corresponding to the variable ‘i’ determined through operations S110 and S140 described above) as the preceding voltage level VPRE. In this case, the training manager 111 may provide the data clock signal WCK_t having the i-th voltage level to the memory device 120 during the preceding voltage period PRE.

The data clock signal WCK_t may toggle during the forty-second time point t42 to the forty-sixth time point t46. That is, the data clock signal WCK_t may repeatedly transition to logic high and transition to logic low during the forty-second time point t42 to the forty-sixth time point t46.

In an embodiment, during the toggle period TGGL, the data clock signal WCK_t may include an odd number of rising edges. For example, during the toggle period TGGL, the data clock signal WCK_t may include 2N−1 rising edges. That is, the number of times of transitions of the data clock signal WCK_t to logic high during the toggle period TGGL may be 2N−1 times.

The divide circuit 121 may generate the internal data clock signal IWCK based on the data clock signal WCK_t. In this case, the logic level of the internal data clock signal IWCK may transition in response to the rising edge of the data clock signal WCK_t. For example, in response to the logic level of the data clock signal WCK_t transitioning to logic high for the first time (i.e., the rising edge of the forty-second time point t42), the internal data clock signal IWCK may transition to logic high at the forty-third time point t43. Thereafter, in response to the logic level of the data clock signal WCK_t transitioning to logic high for the second time, the internal data clock signal IWCK may transition to logic low at the forty-fourth time point t44. In a similar manner, the internal data clock signal IWCK may transition to logic high at the forty-fifth time point t45 and at the forty-seventh time point t47.

That is, according to the embodiment of FIG. 12, the logic level of the internal data clock signal IWCK may transition in response to each rising edge of the data clock signal WCK_t. In this case, in response to ‘2N−1’ rising edges of the data clock signal WCK_t, the number of times of transitions of the internal data clock signal IWCK to logic high will be ‘N’.

The detect circuit 123 may detect a logic level transition of the internal data clock signal IWCK. For example, the counter CNT may count rising edges of the internal data clock signal IWCK. In this case, the count value COUNT may increase by ‘1’ in response to the rising edge of the internal data clock signal IWCK.

For example, the count value COUNT may increase to ‘1’ at the forty-third time point t43, increase to ‘2’ at the forty-fifth time point t45, and increase to ‘N’ at the forty-seventh time point t47.

The detect circuit 123 may determine whether an error is included in the internal data clock signal IWCK based on the count value COUNT after the sufficient time elapses since the forty-sixth time point t46 (that is, after a sufficient time elapses after the toggle period TGGL ends). For example, the detect circuit 123 may determine whether the count value COUNT is ‘N’ after a write leveling output delay tWLO elapses from the forty-sixth time point t46.

When the count value COUNT is ‘N’, the detect circuit 123 may output the feedback data indicating logic high to the host device 110. For example, the detect circuit 123 may control the input/output circuit 126 to output the first data signal DQa indicating logic high to the host device 110 through the first data pin PM_DQa. In this case, the training manager 111 may determine that the internal data clock signal IWCK is normally generated.

In an embodiment, the memory device 120 may reset the count value COUNT stored in the counter CNT in response to the preceding voltage training command PVT. For example, the memory device 120 may reset the count value COUNT before the forty-first time point t41 (or before forty-second time point t42) after the preceding voltage training command PVT is received. However, the scope of the present disclosure is not limited thereto.

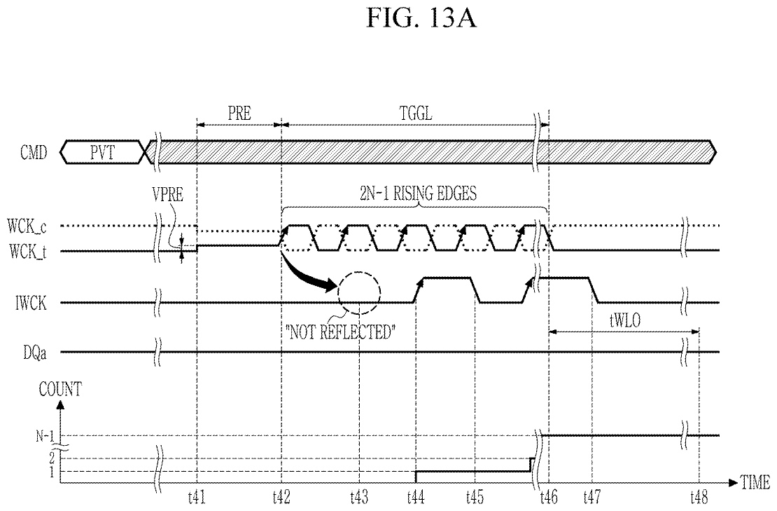

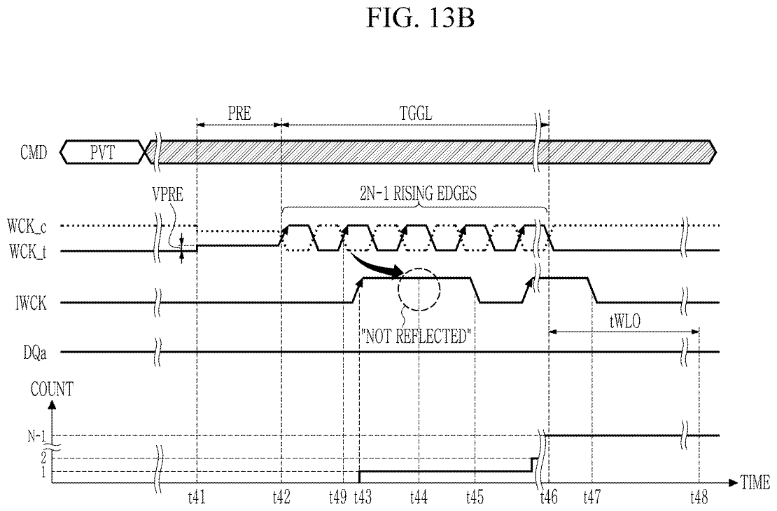

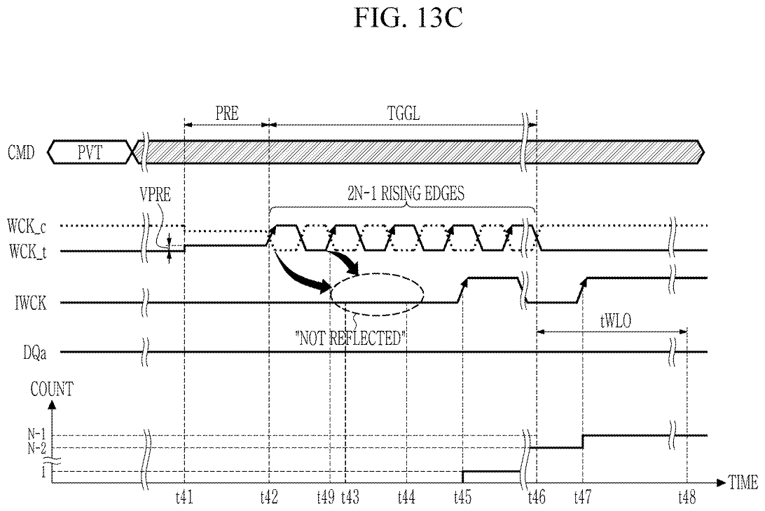

FIGS. 13A to 13C are timing diagrams illustrating operations of a memory device of FIG. 11 according to another embodiment. Hereinafter, an embodiment in which the memory device 120 outputs the feedback data indicating logic low to the host device 110 will be described with reference to FIGS. 1 to 12 and FIGS. 13A to 13C. For a more concise description, a detailed description of the operation of the memory device 120 above described with reference to FIG. 12 will be omitted.

First, referring to FIG. 13A, the divide circuit 121 may operate in the meta-stability state in response to the data clock signal WCK_t at the forty-second time point t42. That is, the divide circuit 121 may not accurately detect the rising edge of the data clock signal WCK_t at the forty-second time point t42. In this case, the rising edge of the data clock signal WCK_t at the forty-second time point t42 may not be reflected in the internal data clock signal IWCK. Therefore, the internal data clock signal IWCK may not transition to logic high at the forty-third time point t43.

Meanwhile, the divide circuit 121 may normally operate in response to the data clock signal WCK_t after the forty-second time point t42. That is, the divide circuit 121 may accurately detect the rising edge of the data clock signal WCK_t after the forty-second time point t42. In this case, the internal data clock signal IWCK will transition to logic high at the forty-fourth time point t44 and transition to logic low at the forty-fifth time point t45. In this way, the internal data clock signal IWCK will transition to logic low at the forty-seventh time point t47.

The count value COUNT may increase to ‘1’ at the forty-fourth time point t44 instead of the forty-third time point t43, and may not increase at the forty-seventh time point t47. That is, according to the embodiment of FIG. 13A, the number of rising edges of the internal data clock signal IWCK may be less than that described with reference to FIG. 12. Accordingly, at the forty-eighth time point t48, the detect circuit 123 may output the first data signal DQa indicating logic low to the host device 110 in response to the count value ‘N−1’.

Next, referring to FIG. 13B, the divide circuit 121 may normally operate in response to the data clock signal WCK_t at the forty-second time point t42. That is, the divide circuit 121 may accurately detect the rising edge of the data clock signal WCK_t at the forty-second time point t42. In this case, the internal data clock signal (IWCK) will transition to logic high at the forty-third time point t43.

On the other hand, the divide circuit 121 may operate in the meta-stability state in response to the data clock signal WCK_t at the forty-ninth time point t49. That is, the divide circuit 121 may not accurately detect the rising edge of the data clock signal WCK_t at the forty-ninth time point t49. In this case, the rising edge of the data clock signal WCK_t at the forty-ninth time point t49 may not be reflected in the internal data clock signal IWCK. Accordingly, the internal data clock signal IWCK may maintain logic high without transitioning to logic low at the forty-fourth time point t44.

Meanwhile, the divide circuit 121 may normally operate in response to the data clock signal WCK_t after the forty-ninth time point t49. That is, the divide circuit 121 may accurately detect the rising edge of the data clock signal WCK_t after the forty-ninth time point t49. In this case, the internal data clock signal IWCK may transition to logic low at the forty-fifth time point t45. In this way, the internal data clock signal IWCK may transition to logic low at the forty-seventh time point t47.

The count value COUNT may increase to ‘1’ at the forty-third time point t43 and may not increase at the forty-seventh time point t47. That is, according to the embodiment of FIG. 13B, the number of rising edges of the internal data clock signal

IWCK may be less than that described with reference to FIG. 12. Accordingly, at the forty-eighth time point t48, the detect circuit 123 may output the first data signal DQa indicating logic low to the host device 110 in response to the count value ‘N−1’.

Next, referring to FIG. 13C, the divide circuit 121 may operate in the meta-stability state in response to the data clock signal WCK_t at the forty-second time point t42 and the forty-ninth time point t49. That is, the divide circuit 121 may not accurately detect the rising edge of the data clock signal WCK_t at the forty-second time point t42 and the forty-ninth time point t49. In this case, the rising edge of the data clock signal WCK_t at the forty-second time point t42 and the forty-ninth time point t49 may not be reflected in the internal data clock signal IWCK. Accordingly, the internal data clock signal IWCK may not transition to logic high at the forty-third time point t43 and the forty-fourth time point t44.

Meanwhile, the divide circuit 121 may normally operate in response to the data clock signal WCK_t after the forty-ninth time point t49. That is, the divide circuit 121 may accurately detect the rising edge of the data clock signal WCK_t after the forty-ninth time point t49. In this case, the internal data clock signal IWCK may transition to logic high at the forty-fifth time point t45. In this way, the internal data clock signal IWCK may transition to logic high at the forty-seventh time point t47.

In this case, the count value COUNT may increase to ‘1’ at the forty-fifth time point t45 and may increase to ‘N−1’ at the forty-seventh time point t47. That is, according to the embodiment of FIG. 13C, the number of rising edges of the internal data clock signal IWCK may be less than that described with reference to FIG. 12. Accordingly, at the forty-eighth time point t48, the detect circuit 123 may output the first data signal DQa indicating logic low to the host device 110 in response to the count value ‘N−1’.

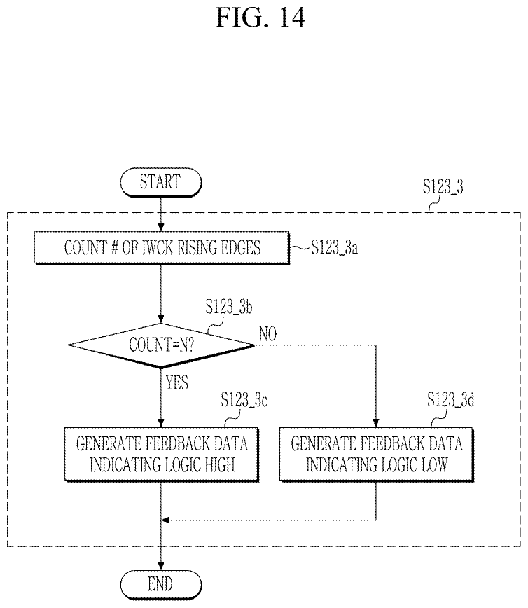

FIG. 14 is a flowchart illustrating an operation of a counter of FIG. 11 in more detail. Referring to FIGS. 1 to 14, operation S123_3 of FIG. 10 may include operations S123_3a to S123_3d below.

In operation S123_3a, the counter CNT may count the number of rising edges of the internal data clock signal IWCK. For example, the count value COUNT stored by the counter CNT may increase by ‘1’ in response to the rising edge of the internal data clock signal IWCK.

In operation S123_3b, the counter CNT may determine whether the count value COUNT is ‘N’. When the count value COUNT is ‘N’, the following operation S123_3c may be performed. When the count value COUNT is not ‘N’, the following operation S123_3d may be performed.

In an embodiment, operation S123_3b may be performed after the write leveling output delay tWLO elapses after the toggle period TGGL ends. However, the scope of the present disclosure is not limited thereto.

In operation S123_3c, the counter CNT may generate the feedback data indicating logic high. For example, the counter CNT may output the first data signal DQa indicating logic high to the host device 110.

In operation S123_3d, the counter CNT may generate the feedback data indicating logic low. For example, the counter CNT may output the first data signal DQa indicating logic low to the host device 110.

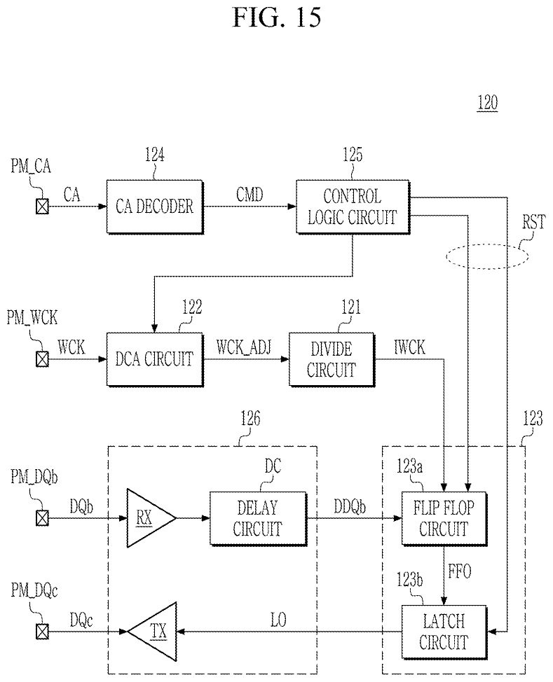

FIG. 15 is a block diagram illustrating the memory device of FIG. 6 implemented according to an embodiment. Referring to FIGS. 1 to 10 and FIG. 15, the memory device 120 may include the divide circuit 121, the DCA circuit 122, the detect circuit 123, the CA decoder 124, the control logic circuit 125, and the input/output circuit 126. The configuration and operation of the divide circuit 121, the DCA circuit 122, the CA decoder 124, and the control logic circuit 125 have been described with reference to FIG. 6, and therefore, detailed descriptions thereof will be omitted.

The input/output circuit 126 may include a receiving circuit RX, a transmitting circuit TX, and a delay circuit DC. The receiving circuit RX may be configured to receive a second data signal DQb through a second data pin PM_DQb. The transmitting circuit TX may be configured to transmit a third data signal DQc through a third data pin PM_DQc. Hereinafter, for more concise description, an embodiment in which the second data pin PM_DQb and the third data pin PM_DQc are different data pins will be representatively described. However, the scope of the present disclosure is not limited thereto, and the receiving circuit RX and the transmitting circuit TX may be connected to one data pin. In this case, the receiving circuit RX and the transmitting circuit TX may operate at different times.

The delay circuit DC may be configured to delay the second data signal DQb provided from the receiving circuit RX. For example, the delay circuit DC may be configured to receive the second data signal DQb and may be configured to output a second delayed data signal DDQb.

The detect circuit 123 may include a flip flop circuit 123a and a latch circuit 123b.

The flip flop circuit 123a may be configured to receive the internal data clock signal IWCK. The flip flop circuit 123a may be configured to receive the second delayed data signal DDQb. The flip flop circuit 123a may be configured to operate in response to the rising edge of the internal data clock signal IWCK. For example, the flip flop circuit 123a may be configured to detect the second delayed data signal DDQb in response to the rising edge of the internal data clock signal IWCK.

In an embodiment, the internal data clock signal IWCK may be provided to a clock terminal of the flip flop circuit 123a.

The flip flop circuit 123a may be configured to provide the flip flop output signal FFO to the latch circuit 123b. In this case, the logic level of the flip flop output signal FFO may vary depending on whether the second delayed data signal DDQb is detected in response to the rising edge of the internal data clock signal IWCK.

The latch circuit 123b may be configured to buffer the flip flop output signal FFO. The latch circuit 123b may be configured to provide the latch output signal LO corresponding to the logic level of the flip flop output signal FFO to the transmitting circuit TX. In this case, the latch output signal LO may correspond to the feedback data signal.

In an embodiment, the length of time delayed by the delay circuit DC may correspond to a length of a path delay between the data clock pad PM_WCK and the flip flop circuit 123a. For example, the time interval from the time when the data clock signal WCK received by the data clock pad PM_WCK enters the toggle period TGGL to the time at which the logic level of the internal data clock signal IWCK provided to the flip flop circuit 123a transitions to logic high may be referred to as ‘internal delay time’. In this case, the delay time length of the delay circuit DC may be the same as the above-described internal delay time. However, the scope of the present disclosure is not limited thereto.

The control logic circuit 125 may be configured to reset the detect circuit 123 in response to the command CMD provided from the CA decoder 124. For example, the control logic circuit 125 may be configured to provide a reset signal RST to the flip flop circuit 123a and the latch circuit 123b in response to the preceding voltage training command PVT, so the flip flop circuit 123a and the latch circuit 123b may be reset.

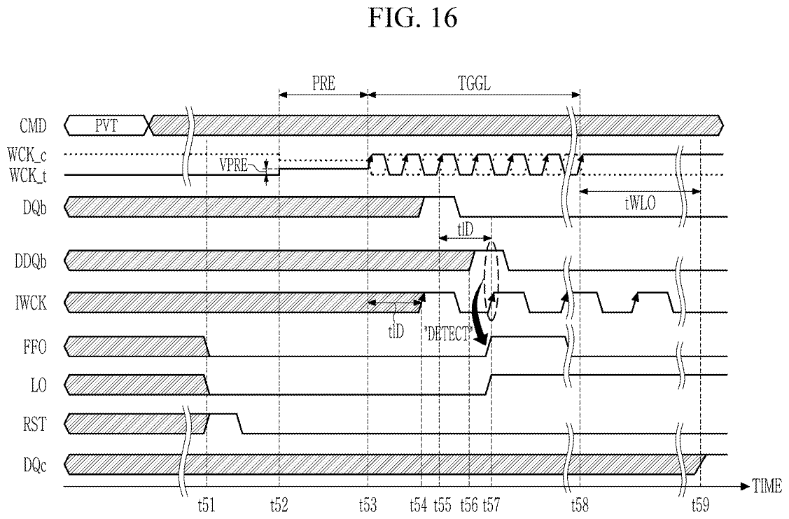

FIG. 16 is a timing diagram illustrating an operation of the memory device of FIG. 15 according to an embodiment. Hereinafter, the embodiment in which the memory device 120 outputs the feedback data indicating logic high to the host device 110 will be described with reference to FIG. 16.

Referring to FIGS. 1 to 10 and FIGS. 15 and 16, the memory device 120 may receive the preceding voltage training command PVT from the host device 110. For example, the memory device 120 may receive the command/address signals CA indicating the preceding voltage training command PVT from the host device 110.

After the preceding voltage training command PVT is received, the reset signal RST may transition to a logic high at a fifty-first time point t51. In this case, the flip flop circuit 123a and the latch circuit 123b may be reset in response to the reset signal RST that is logic high.

After receiving the preceding voltage training command PVT, the memory device 120 may receive the data clock signals WCK including the preceding voltage period PRE and the toggle period TGGL from the host device 110. In this case, the preceding voltage period PRE may correspond to a time period between a fifty-second time point t52 and a fifty-third time point t53. The toggle period TGGL may correspond to a time period between the fifty-third time point t53 and a fifty-eighth time point t58.

The voltage level of the data clock signals WCK during the preceding voltage period PRE may be determined in a manner similar to that described above with reference to FIG. 12, and therefore, detailed descriptions thereof will be omitted.

The data clock signal WCK_t may be toggled during the fifty-third time point t53 to the fifty-eighth time point t58. That is, the data clock signal WCK_t may repeat the transitions between logic high and logic low during the fifty-third time point t53 to the fifty-eighth time point t58.

The data clock signal WCK_t may transition to logic high at the fifty-third time point t53 for the first time. In this case, the internal data clock signal IWCK may transition to logic high at a fifty-fourth time point t54 when an internal delay time tID elapses from a fifty-third time point t53.

The data clock signal WCK_t may transition to logic high for the third time at a fifty-fifth time point t55. In this case, the internal data clock signal IWCK may transition to logic high at a fifty-seventh time point t57 when the internal delay time tID elapses from the fifty-fifth time point t55.

The training manager 111 may provide the second data signal DQb aligned with the third rising edge of the data clock signal WCK_t within the toggle period TGGL to the memory device 120. That is, the training manager 111 may provide the second data signal DQb, which is logic high, to the memory device 120 at the fifty-fifth time point t55.

The delay circuit DC may generate the second delayed data signal DDQb by delaying the second data signal DQb by the internal delay time tID. In this case, the second delayed data signal DDQb may be a logic high from the fifty-fifth time point t55 to the fifty-seventh time point t57 when the internal delay time tID elapses.

That is, according to the embodiment of FIG. 16, the flip flop circuit 123a may detect the logic level of the second delayed data signal DDQb in response to the rising edge of the internal data clock signal IWCK at the fifty-seventh time point t57. In this case, the flip flop output signal FFO may transition to logic high at the fifty-seventh time point t57.

In an embodiment, the flip flop output signal FFO may transition to logic low in response to the rising edge of the internal data clock signal IWCK after the fifty-seventh time point t57. However, the scope of the present disclosure is not limited thereto.

The latch output signal LO may transition to logic high in response to the rising edge of the flip flop output signal FFO. For example, the latch output signal LO may maintain logic high after the fifty-seventh time point t57.

In an embodiment, the latch output signal LO may indicate whether the data clock signal IWCK was normally generated by allowing the divide circuit 121 to accurately detect the rising edge of the data clock signal WCK_t between the fifty-third time point t53 to the fifty-fifth time point t55. For example, after the fifth-seventh time point t57, the logic level of the latch output signal LO may correspond to the feedback data.

The transmitting circuit 123 may output a third data signal DQc (i.e., feedback data) corresponding to the latch output signal LO after a sufficient time has elapsed after the fifty-eighth time point t58 (i.e., after a sufficient time has elapsed after the toggle period TGGL ends). For example, the transmitting circuit 123 may output a third data signal DQc corresponding to the logic level of the latch output signal LO to the host device 110 at a fifty-ninth time point t59 after a write leveling output delay tWLO has elapsed since the fifty-eighth time point t58.

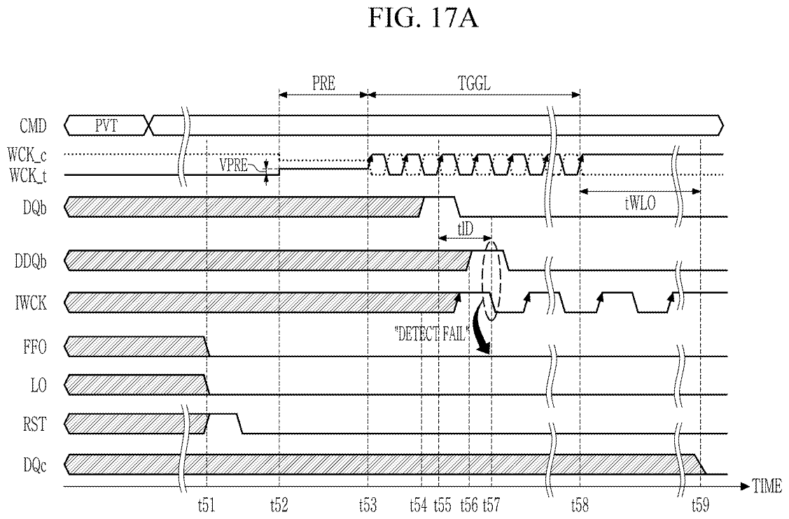

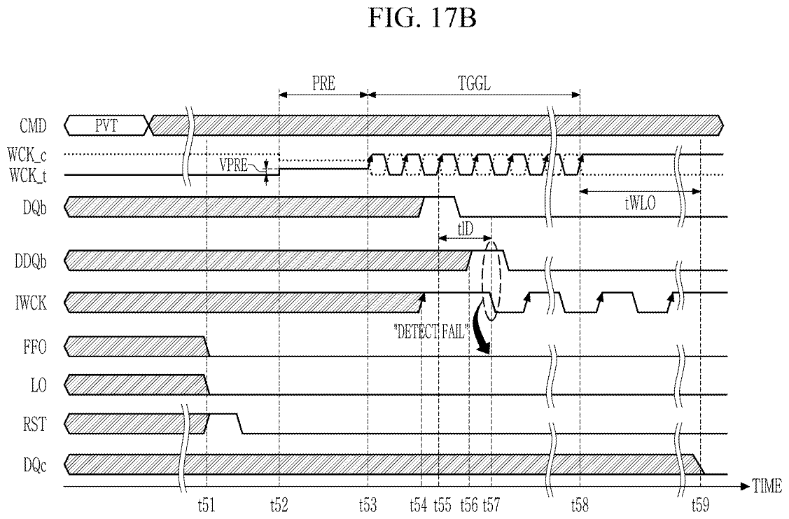

FIGS. 17A to 17B are timing diagrams illustrating operations of a memory device of FIG. 15 according to another embodiment. Hereinafter, an embodiment in which the memory device 120 outputs the feedback data indicating logic low to the host device 110 will be described with reference to FIGS. 1 to 10, FIGS. 15 and 16, and FIGS. 17A to 17B. For a more concise description, a detailed description of the operation of the memory device 120 above described with reference to FIG. 16 will be omitted.

First, referring to FIG. 17A, the divide circuit 121 may operate in the meta-stability state in response to the data clock signal WCK_t at the fifty-third time point t53. That is, the divide circuit 121 may not accurately detect the rising edge of the data clock signal WCK_t at the fifty-third time point t53. In this case, the rising edge of the data clock signal WCK_t at the fifty-third time point t53 may not be reflected in the internal data clock signal IWCK. Therefore, the internal data clock signal IWCK may not transition to logic high at the fifty-fourth time point t54.

Meanwhile, the divide circuit 121 may normally operate in response to the data clock signal WCK_t after the fifty-third time point t53. That is, the divide circuit 121 may accurately detect the rising edge of the data clock signal WCK_t after the fifty-third time point t53. In this case, compared to the embodiment described with reference to FIG. 16, a logic level transition time of the internal data clock signal IWCK may be delayed. In this way, the internal data clock signal IWCK may transition to logic low at the fifty-seventh time point t57.

That is, according to the embodiment of FIG. 17A , the rising edge of the internal data clock signal IWCK may not be included within the time period in which the second delayed data signal DDQb maintains logic high. In this case, the flip flop circuit 123a may not detect logic high of the second delayed data signal DDQb. Accordingly, the flip flop output signal FFO and the latch output signal LO may maintain logic low.

The transmitting circuit 123 may output the third data signal DQc corresponding to the logic level of the latch output signal LO to the host device 110 at the fifty-ninth time point t59. That is, at the fifty-ninth time point t59, the transmitting circuit 123 may output the feedback data indicating logic low to the host device 110.

Next, referring to FIG. 17B, the divide circuit 121 may normally operate in response to the data clock signal WCK_t at the fifty-third time point t53. That is, the divide circuit 121 may accurately detect the rising edge of the data clock signal WCK_t at the fifty-third time point t53. In this case, the internal data clock signal IWCK may transition to logic high at the fifty-fourth time point t54.

On the other hand, the divide circuit 121 may operate in the meta-stability state in response to the second rising edge of the data clock signal WCK_t. That is, the divide circuit 121 may not accurately detect the rising edge of the data clock signal WCK_t at the forty-ninth time point t49. In this case, compared to the embodiment described with reference to FIG. 16, the time period in which the internal data clock signal IWCK maintains logic high may be long. For example, the internal data clock signal IWCK will transition to logic high at the fifty-fourth time point t54 and transition to logic low at the fifty-seventh time point t57.

That is, according to the embodiment of FIG. 17B, the rising edge of the internal data clock signal IWCK may not be included within the time period in which the second delayed data signal DDQb maintains logic high. In this case, the transmitting circuit 123 may output the third data signal DQc indicating logic low to the host device 110 at the fifty-ninth time point t59.

FIG. 18 is a diagram illustrating a table stored in a training manager of FIG. 1 according to an embodiment of the disclosure. Referring to FIGS. 1, 4 to 10, and 18, the training manager 111 may be configured to store the feedback data provided from the memory device 120 as a table TB. For example, the training manager 111 may be configured to store the logic level of the feedback data for the combination of the preceding voltage level VPRE and the DCA code in the table TB.

For a more detailed example, after a DCA command for changing the DCA code to ‘−7’ is provided to the memory device 120, the feedback data returned from the memory device 120 based on the data clock signals WCK in which the preceding voltage level VPRE is the first voltage level V1 may be logic low L. In this case, the training manager 111 may be configured to store the ‘logic low L’ for the first voltage level V1 and the DCA code ‘−7’.

After the DCA command for changing the DCA code to ‘0’ is provided to the memory device 120, the feedback data returned from the memory device 120 based on the data clock signals WCK in which the preceding voltage level VPRE is a third voltage level V3 may be logic high H. In this case, the training manager 111 may be configured to store the logic high H for the third voltage level V3 and the DCA code ‘0’.

In this way, the training manager 111 may be configured to store the table TB for combinations of the first to fifth voltage levels V1 to V5 and the DCA codes ‘−7’ to ‘+7’. However, the scope of the present disclosure is not limited to the number of voltage levels and the number of DCA codes of the table TB managed by the training manager 111.

The training manager 111 may be configured to determine the optimal preceding voltage level based on the number of ‘H’s corresponding to each of the first to fifth voltage levels V1 to V5 in the table TB. For example, the training manager 111 may be configured to determine a voltage level corresponding to the largest number of ‘H’s among the first to fifth voltage levels V1 to V5 as the optimal preceding voltage level.

For a more detailed example, for the first voltage level V1, there are four ‘H’s (e.g., ‘−2’, ‘−1’, ‘0’, and ‘1’ DCA codes) may be stored in the table TB. In similar way, the number of ‘H’s for the second to fifth voltage levels V2 to V5 may be ‘6’, ‘9’, ‘9’, and ‘4’, respectively. In this case, the training manager 111 may determine the third voltage level V3 or the fourth voltage level V4 corresponding to the largest number of ‘Hs’ as the optimal preceding voltage level.

In an embodiment, when there are two or more preceding voltage levels VPRE corresponding to the same number of ‘H’s, the training manager 111 may determine the optimal preceding voltage level based on a range of the DCA code indicating ‘H’. For example, when the third voltage level V3 is the preceding voltage level VPRE, the DCA codes corresponding to ‘H’ may be ‘−4’ to +4′. On the other hand, when the fourth voltage level V4 is the preceding voltage level VPRE, the DCA codes corresponding to ‘H’ may be ‘−1’ to +7′. That is, the number of ‘H’s corresponding to the third voltage level V3 and the fourth voltage level V4, respectively, may be nine. In this case, the training manager 111 may determine a third voltage level V3, in which the range of the feedback data indicating logic high is more adjacent to the DCA code ‘0’, as the optimal preceding voltage level. For example, the training manager 111 may determine, as the optimal preceding voltage level, the third voltage level V3 in which an average of the DCA codes corresponding to the feedback data indicating logic high H is closer to ‘0’. However, the scope of the present disclosure is not limited thereto.

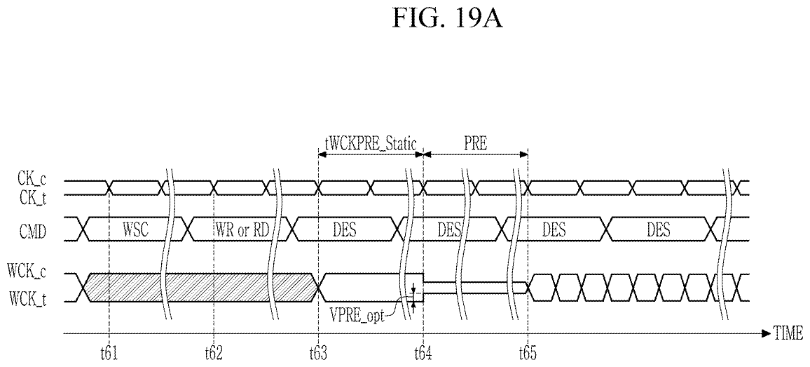

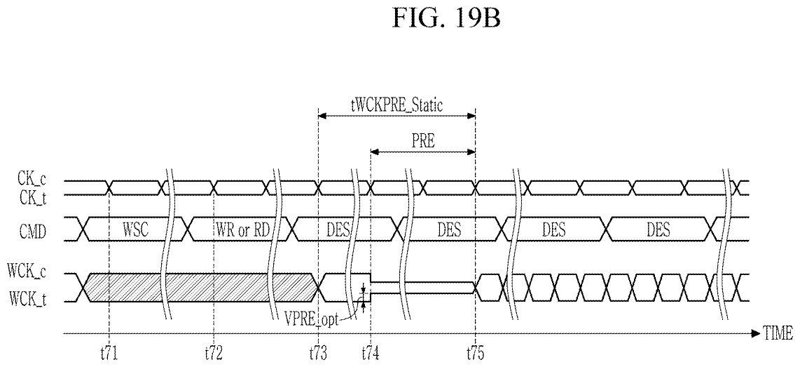

FIGS. 19A and 19B are timing diagrams illustrating an operation of a memory device based on an optimal preceding voltage level according to an embodiment of the present disclosure. Hereinafter, a data clock synchronization (WCK2CK synchronization) operation of the memory device 120 will be described with reference to FIGS. 1 and 19A to 19B.

First, referring to FIGS. 1 and 19A, at a sixty-first time point t61, the memory device 120 may receive a data clock synchronize command WSC.

In an embodiment, the data clock synchronize command WSC may be a CAS command provided by setting at least one of ‘WS_WR’ operand and the ‘WS_RD’ operand to logic high.

In an embodiment, the data clock synchronize command WSC may be provided to the memory device 120 along 2-cycles of the clock signal CK_t. However, the scope of the present disclosure is not limited thereto.

At a sixty-second time point t62, the memory device 120 may receive a read command RD or a write command WR.

In an embodiment, the command provided to the memory device 120 at the sixty-second time point t62 may correspond to the operand of the data clock synchronize command WSC. However, the scope of the present disclosure is not limited thereto.

In an embodiment, the memory device 120 may receive various types of commands (e.g., data clock synchronize command WSC, read command RD, or write command WR) based on the clock signal CK_t and the inverted clock signal CK_c. In this case, the clock signal CK_t and the inverted clock signal CK_c may be included in the clock signal CK of FIG. 1. However, the scope of the present disclosure is not limited thereto.

From a sixty-third time point t63 to a sixty-fourth time point t64, the memory device 120 may be in a static period tWCKPRE_static.

In an embodiment, the static period tWCKPRE_static may be a time required for supplying power to a buffer circuit included in the memory device 120. However, the scope of the present disclosure is not limited thereto.

From a sixty-fourth time point t64 to a sixty-fifth time point t65, the memory device 120 may receive the data clock signals WCK corresponding to an optimal preceding voltage level VPRE_opt. For example, the memory device 120 may receive data clock signals WCK_t having the optimal preceding voltage level VPRE_opt. In this case, the time period between the sixty-fourth time point t64 to the sixty-fifth time point t65 may be the preceding voltage period PRE described above with reference to FIGS. 1 to 18.

In an embodiment, the length of the preceding voltage period PRE may be 1tCK, i.e., one period of the clock signal. For example, the length of the preceding voltage period PRE may be equal to the period of the clock signal CK_t. However, the scope of the present disclosure is not limited thereto.

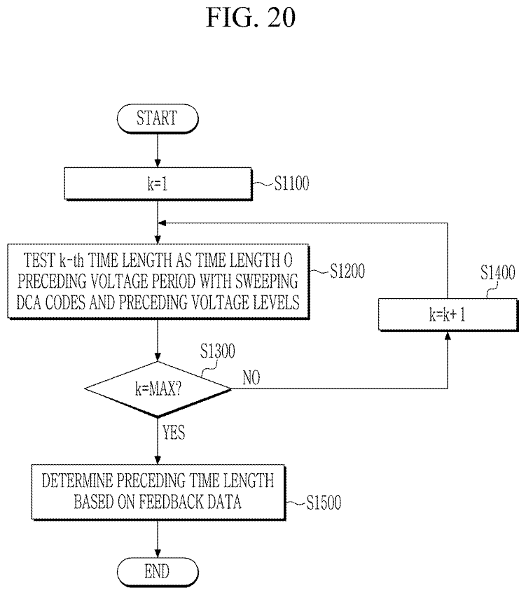

In an embodiment, the length of the preceding voltage period PRE may be determined through training. A specific method for determining the length of the preceding voltage period PRE through training will be described in more detail with reference to FIG. 20 below.

After the sixty-fifth time point t65, the data clock signals WCK provided to the memory device 120 may be at full-toggle frequency. That is, according to an embodiment of the present disclosure, while the data clock synchronization operation is performed, a period in which the data clock signals WCK toggle at a frequency half of the full-toggle frequency may be omitted. Accordingly, according to an embodiment of the present disclosure, read latency RL and write latency WL may be reduced. In this case, the read and write speeds of the memory device 120 may be improved.

In an embodiment, the frequency of the full-toggle data clock signals WCK may be 4800 MHZ. However, the scope of the present disclosure is not limited thereto.

Referring to FIGS. 1 and 19B, at a seventy-first time point t71, the memory device 120 may receive a data clock synchronize command (WSC). At the seventy-first time point t71, the memory device 120 may receive the read command RD or the write command WR. The operations of the memory device 120 at the seventy-first time point t71 to the seventy-second time point t72 are similar to those described with reference to FIG. 19A described above, and therefore, detailed descriptions thereof will be omitted.

From the seventy-third t73 to the seventy-fifth time point t75, the memory device 120 may be in the static period tWCKPRE_static. Meanwhile, from the seventy-fourth time point t74 to the seventy-fifth time point t75, the memory device 120 may receive the data clock signals WCK corresponding to the optimal preceding voltage level VPRE_opt. That is, the seventy-fourth time point t74 to the seventy-fifth time point t75 may be the preceding voltage period PRE described with reference to FIGS. 1 to 18.

After the seventy-fifth time point t75, the data clock signals WCK provided to the memory device 120 may be at full-toggle frequency. That is, unlike the embodiment previously described with reference to FIG. 19A, according to the embodiment of FIG. 19B, the preceding voltage period PRE may be included in the static period tWCKPRE_static. In this case, the read delay and write delay may be reduced by the time length of the preceding voltage period PRE.

FIG. 20 is a flowchart illustrating a method of operating a memory system according to an embodiment of the present disclosure. Referring to FIGS. 1 to 10 and 20, in operation S1100, a variable ‘k’ may be set to ‘1’. The variable k is only used to describe a repetitive operation of the memory system 100 and does not limit the scope of the present disclosure.

In operation S1200, the memory system 100 sweeps the DCA codes and the preceding voltage levels, and may test a k-th time length as the time length of the preceding voltage period. For example, the host device 110 may store the feedback data for each of various combinations of the DCA codes and the preceding voltage levels. In this case, operation S1200 may include operations S110 to S140 previously described with reference to FIG. 8. However, the scope of the present disclosure is not limited thereto.

In an embodiment, the k-th time length may be an integer multiple of half of the period of the clock signal CK. For example, the k-th time length may be an integer multiple of 0.5tCK. However, the scope of the present disclosure is not limited thereto.

In operation S1300, the memory system 100 may determine whether variable k is maximum. For example, the host device 110 may determine whether all time lengths are tested as time lengths of the preceding voltage period.

In an embodiment, when the host device 110 determines that the untested time length remains as the time length of the preceding voltage period, the following operation S1400 may be performed.

In an embodiment, when the host device 110 determines that all time lengths are tested as the time lengths of the preceding voltage period, the following operation S1500 may be performed.

In operation S1400, the variable ‘k’ may be increased by ‘1’. Thereafter, the above-described operation S1200 may be repeatedly performed.

In operation S1500, the memory system 100 may determine the time length of the optimal preceding voltage period based on the feedback data. For example, the training manager 111 may determine the time length of the optimal preceding voltage period based on the feedback data provided from the memory device 120 through the repeatedly performed operation S1200. In this case, the optimal preceding voltage level may be one of the time lengths tested in the repeatedly performed operation S1200. The operation of the memory system 100 in operation S1500 may be similar to the method described above with reference to FIG. 18, and therefore, detailed descriptions thereof will be omitted.

The foregoing are specific embodiments for carrying out the present disclosure. The present disclosure will include not only the above-described embodiments, but also embodiments that can be simply or easily changed in design. In addition, the present disclosure will also include technologies that can be easily modified and implemented using the embodiments. Therefore, the scope of the present disclosure should not be limited to the above-described embodiments and should be defined by not only the claims to be described later but also those equivalent to the claims of the present disclosure.

What is claimed is:

1. A memory device, comprising:
a divide circuit configured to generate an internal data clock signal based on a data clock signal, wherein the data clock signal has a first voltage level for a first time period and toggles during a second time period consecutive to the first time period;
a detect circuit configured to generate a feedback data corresponding to the first voltage level based on the internal data clock signal; and
an input/output circuit configured to output the feedback data to an external device.

2. The memory device of claim 1, wherein:
the feedback data indicates whether a logic level of the internal data clock signal changes in response to all rising edges included in the second time period of the data clock signal.

3. The memory device of claim 1, wherein:
a frequency of the internal data clock signal is half of a frequency of the data clock signal.

4. The memory device of claim 1, wherein the detect circuit includes:
a counter configured to store a count value that increases in response to each rising edge of the internal data clock signal included in the second time period.

5. The memory device of claim 4, wherein:
a number of rising edges of the internal data clock signal included in the second time period is ‘2N−1’ (wherein, ‘N’ is an integer greater than or equal to 1), when the count value is ‘N’, the feedback data is configured to indicate logic high, and
when the count value is not ‘N’, the feedback data is configured to indicate logic low.

6. The memory device of claim 1, wherein:
the input/output circuit includes:
a receiving circuit configured to receive a first data signal from the external device;
a transmitting circuit configured to output the feedback data to the external device; and
a delay circuit configured to receive the first data signal and configured to generate a first delayed data signal, and
the detect circuit includes:
a flip flop circuit configured to receive the first delayed data signal and configured to operate in response to rising edges of the internal data clock signal; and
a latch circuit configured to provide the feedback data to the transmitting circuit based on an output signal of the flip flop circuit.

7. The memory device of claim 6, wherein:
the first delayed data signal is logic high between a first time point and a second time point,
when a rising edge of the internal data clock signal is provided to the flip flop circuit between the first time point and the second time point, the flip flop circuit is configured to output the output signal indicating logic high, and the latch circuit is configured to output the feedback data indicating logic high, and
when the rising edge of the internal data clock signal is not provided to the flip flop circuit between the first time point and the second time point, the flip flop circuit is configured to output the output signal indicating logic low, and the latch circuit is configured to output the feedback data indicating logic low.

8. The memory device of claim 6, wherein:
the delay circuit is configured to delay the first data signal by a first time length corresponding to a path delay length between a data clock pad configured to receive the data clock signal from the external device and the flip flop circuit.

9. The memory device of claim 1, further comprising a duty cycle adjuster (DCA) circuit connected between the data clock pad and the divide circuit, wherein:
the DCA circuit is configured to generate an adjusted data clock signal by adjusting a duty cycle of the data clock signal in response to a control signal from the external device, and
the divide circuit is configured to generate the internal data clock signal based on the adjusted data clock signal.

10. A method of operating a memory system including a host device configured to output a data clock signal including a preceding voltage period and a toggle period, and a memory device configured to receive the data clock signal, the method comprising:
providing, by the memory device, a first plurality of feedback data generated based on a first data clock signal having a first voltage level during the preceding voltage period to the host device;
providing, by the memory device, a second plurality of feedback data generated based on a second data clock signal having a second voltage level during the preceding voltage period to the host device;
determining, by the host device, an optimal preceding voltage level based on the first plurality of feedback data and the second plurality of feedback data; and
performing, by the host device, a data clock synchronize operation for the memory device based on a third data clock signal having the optimal preceding voltage level during the preceding voltage period,
wherein each of the first plurality of feedback data is generated based on different duty cycle adjuster (DCA) codes, and each of the second plurality of feedback data is generated based on the different DCA codes.

11. The method of claim 10, wherein the memory device includes:
a DCA circuit receiving the data clock signal and outputting an adjusted data clock signal based on a set DCA code; and
a divide circuit receiving the adjusted data clock signal and outputting an internal data clock signal.

12. The method of claim 11, wherein:
the providing the first plurality of feedback data to the host device includes:
transmitting, by the host device, a first DCA command to the memory device;
setting, by the memory device, the DCA circuit with a first DCA code in response to the first DCA command;
transmitting, by the host device, a first preceding voltage training command to the memory device;
transmitting, by the host device, the first data clock signal to the memory device;
determining, by the memory device, whether the internal data clock signal is normally generated in response to the first data clock signal; and
outputting, by the memory device, one of the first plurality of feedback data based on a result of the determining.

13. The method of claim 11, wherein each of the first plurality of feedback data and the second plurality of feedback data is configured to:
indicate logic high when the internal data clock signal is normally generated in response to the adjusted data clock signal based on the corresponding DCA code, and
indicate logic low when the internal data clock signal is not normally generated in response to the adjusted data clock signal based on the corresponding DCA code.

14. The method of claim 13, wherein the optimal preceding voltage level is determined based on:
a first number of feedback data indicating logic high from among the first plurality of feedback data; and
a second number of feedback data indicating logic high from among the second plurality of feedback data.

15. The method of claim 14, wherein, when the first number and the second number are identical, the optimal preceding voltage level is determined based on:
a first range of the different DCA codes corresponding to the feedback data indicating logic high from among the first plurality of feedback data; and
a second range of the different DCA codes corresponding to the feedback data indicating logic high from among the second plurality of feedback data.

16. The method of claim 10, wherein the optimal preceding voltage level is the first voltage level or the second voltage level.

17. The method of claim 10, wherein the preceding voltage period is included in a static period in the data clock synchronize operation.

18. A method of operating a memory system including a host device and a memory device, comprising:
providing, by the host device, a first preceding voltage training command to the memory device;
transmitting, by the host device, a first data clock signal to the memory device, wherein the first data clock signal is configured to have a first voltage level from a first time point to a second time point, to toggle from the second time point to a third time point, and to cease toggling after the third time point;
providing, by the memory device, a first feedback data for the first voltage level to the host device in response to the first preceding voltage training command after a first time length has elapsed from the third time point;
providing, by the host device, a second preceding voltage training command to the memory device;
transmitting, by the host device, a second data clock signal to the memory device, wherein the second data clock signal is configured to have a second voltage level from a fourth time point to a fifth time point, to toggle from the fifth time point to a sixth time point, and to cease toggling after the sixth time point; and
providing, by the memory device, a second feedback data for the second voltage level in response to the second preceding voltage training command after the first time length has elapsed from the sixth time point.

19. The method of claim 18, further comprising:
transmitting, by the host device, a data clock synchronize command to the memory device; and
providing, by the host device, a third data clock signal to the memory device,
wherein the third data clock signal is configured to have a third voltage level from a seventh time point to an eighth time point, and to toggle after the eighth time point, and
wherein the third voltage level is determined based on the first and second feedback data.

20. The method of claim 18, wherein the memory device includes a divide circuit generating a first internal data clock signal based on the first data clock signal and a second internal data clock signal based on the second data clock signal, wherein:
the first feedback data is determined based on a number of rising edges included in the first internal data clock signal, and
the second feedback data is determined based on a number of rising edges included in the second internal data clock signal.
